(19) United States
(12) Patent Application Publication
(10) Pub. No.: US 2017/0218500 A1
(43) Pub. Date: Aug. 3, 2017

(54) VAPOR DEPOSITION DEVICE, VAPOR DEPOSITION METHOD, AND ORGANIC EL ELEMENT

(71) Applicant: Sharp Kabushiki Kaisha, Sakai City (JP)

(72) Inventors: Takashi OCHI, Sakai City (JP); Shinichi KAWATO, Sakai City (JP); Yuhki KOBAYASHI, Sakai City (JP); Kazuki MATSUNAGA, Sakai City (JP); Katsuhiro KIKUCHI, Sakai City (JP); Masahiro ICHIHARA, Mitsuke-shi (JP); Eiichi MATSUMOTO, Mitsuke-shi (JP)

(73) Assignee: Sharp Kabushiki Kaisha, Sakai City (JP)

(21) Appl. No.: 15/500,856

(22) PCT Filed: Jul. 24, 2015
(86) PCT No.: PCT/JP2015/071084

§ 371 Date: Jan. 31, 2017

(30) Foreign Application Priority Data
Aug. 1, 2014 (JP) 2014-158220

(51) Int. Cl. C23C 14/24

(52) U.S. Cl. CPC C23C 14/24; C23C 14/246; C23C 14/243; H01L 51/50

(57) ABSTRACT

A vapor deposition device is provided with first and second vapor deposition sources, a common pipe that is connected to the first and second vapor deposition sources, a vapor deposition particle emission source that is connected to the common pipe and emits vapor deposition particles from each of the first and second vapor deposition sources, an exhaust valve that is connected to the vapor deposition particle emission source, and an exhaust pump that is connected to the exhaust valve.

### CROSS-REFERENCE TO RELATED APPLICATIONS

This application is a U.S. National Phase patent application of International Patent Application No. PCT/JP2015/071084, filed Jul. 24, 2015, which claims priority to Japanese Application No. 2014-158220, filed Aug. 1, 2014, each of which is hereby incorporated by reference in the present disclosure in its entirety.

### FIELD OF THE INVENTION

The present invention relates to a vapor deposition device and a vapor deposition method for forming a film on a substrate. In particular, the present invention relates to a vapor deposition device and a vapor deposition method for performing co-deposition of two or more types of materials. The present invention also relates to an organic EL (Electro Luminescence) element that has a light emitting layer or the like formed by vapor deposition.

### BACKGROUND OF THE INVENTION

In recent years, flat panel displays have been used in various products and fields, and there is demand for flat panel displays to have bigger sizes, higher definition, and lower power consumption.

In light of this situation, organic EL (Electro Luminescence) display apparatuses, which include an organic EL element that utilizes the electroluminescence of an organic material, have gained a lot of attention as flat panel displays that are all-solid and superior in terms of low voltage drivability, fast response, self luminescence, and the like.

An organic EL element such as that described above is provided with an anode, a cathode, and a light emitting layer formed between the anode and the cathode. Also, in order to achieve an improvement in luminous efficiency and the like in the light emitting layer, this kind of organic EL element has been provided with a hole injection layer and a hole transport layer between the anode and the light emitting layer, and provided with an electron injection layer and an electron transport layer between the cathode and the light emitting layer. Furthermore, various constituent elements such as the light emitting layer of this kind of organic EL element have been formed using vacuum deposition for example. Specifically, in the organic EL element, various constituent elements are formed as necessary on a substrate, which serves as the base, by successively emitting vapor deposition particles that correspond to the constituent elements onto the substrate in a vacuum chamber provided in a vapor deposition device.

Also, it is known that the light emitting layer of an organic EL element is formed using a doping method in which an additive material (guest compound) called the “dopant” is added to a base material called the “host” with the goal of obtaining a desired luminescent color, improving the luminous efficiency, or the like in the light emitting layer.

Specifically, with conventional vapor deposition devices, there has been a proposal for forming the light emitting layer by co-deposition of vapor deposition particles of a host material and vapor deposition particles of a dopant material, as described in Patent Document 1 noted below for example.

Specifically, as shown in FIG. 24, this conventional vapor deposition device 100 includes a first vapor deposition source 101 that produces vapor deposition particles of a host material 103h, a second vapor deposition source 102 that produces vapor deposition particles of a dopant material 103d, and a vapor deposition particle emission source 107 that is provided in a vacuum chamber 104 and emits, onto a substrate 105, a vapor deposition particle mixture 106 in which vapor deposition particles of the host material 103h from the first vapor deposition source 101 are mixed with vapor deposition particles of the dopant material 103d from the second vapor deposition source 102.

The first vapor deposition source 101 is provided with a crucible 101a and a heater 101b that heats the interior of the crucible 101a, and the first vapor deposition source 101 produces vapor deposition particles of the host material 103h by heating the host material 103h placed inside the crucible 101a. A pipe 108 provided with a valve 108a is connected to the first vapor deposition source 101. Also, this pipe 108 is provided with a rate monitor 110 that monitors the particle amount of vapor deposition particles (vapor deposition particle concentration) of the host material 103h flowing inside the pipe 108.

The second vapor deposition source 102 is provided with a crucible 102a and a heater 102b that heats the interior of the crucible 102a, and the second vapor deposition source 102 produces vapor deposition particles of the dopant material 103d by heating the dopant material 103d placed inside the crucible 102a. A pipe 109 provided with a valve 109a is connected to the second vapor deposition source 102. Also, this pipe 109 is provided with a rate monitor 111 that monitors the particle amount of vapor deposition particles (vapor deposition particle concentration) of the dopant material 103d flowing inside the pipe 109.

Also, one end of a mixing pipe 112 is connected to the vapor deposition particle emission source 107, the other end is connected to the pipes 108 and 109, and vapor deposition particles of the host material 103h and vapor deposition particles of the dopant material 103d are mixed inside the mixing pipe 112, thus producing the vapor deposition particle mixture 106.

In this conventional vapor deposition device 100, the vapor deposition particle mixture 106 including vapor deposition particles of the host material 103h and vapor deposition particles of the dopant material 103d is emitted to form a light emitting layer that is made up of the vapor deposition particle mixture 106.

### PRIOR ART DOCUMENTS

[Patent Document 1] WO 2012/098927 pamphlet

### SUMMARY OF THE INVENTION

However, in the above-described conventional vapor deposition device 100, vapor deposition particles of the host material 103h and vapor deposition particles of the dopant material 103d are mixed inside the mixing pipe 112. For this reason, in this conventional vapor deposition device 100, there have been cases where the ratio of concentration of the host material 103h and the dopant material 103d in the formed light emitting layer (co-deposition film) does not match the ratio of the concentration of vapor deposition particles of the host material 103h and the concentration of vapor deposition particles of the dopant material 103d observed by the rate monitors 110 and 111, due to mutual interference between the pressure of vapor deposition particles of the host material 103h flowing from the pipe 108 into the mixing pipe 112 and the pressure of vapor deposition particles of the dopant material 103d flowing from the pipe 109 into the mixing pipe 112, for example. For this reason, when performing co-deposition of the host material 103h and the dopant material 103d in this conventional vapor deposition device 100, there have been problems such as that a desired value cannot be obtained for the ratio of concentration of the host material 103h and the dopant material 103d, and a co-deposition film of these materials cannot been formed precisely.

In light of the above-described issues, an object of the present invention is to provide a vapor deposition device and a vapor deposition method that, even when performing co-deposition of two or more types of materials, can precisely form a co-deposition film, and an organic EL element using the same.

In order to achieve the object described above, a vapor deposition device according to the present invention includes: a plurality of vapor deposition sources;

at least one common pipe that is connected to the plurality of vapor deposition sources;

at least one vapor deposition particle emission source that is connected to the at least one common pipe and emits vapor deposition particles from each of the vapor deposition sources;

an exhaust valve that is connected to the at least one vapor deposition particle emission source; and

an exhaust pump that is connected to the exhaust valve.

In the vapor deposition device having the above configuration, multiple vapor deposition sources are connected to the at least one common pipe, and vapor deposition particles from each of the vapor deposition sources are emitted from the at least one vapor deposition particle emission source that is connected to the at least one common pipe. Also, the exhaust valve and the exhaust pump are connected to the at least one vapor deposition particle emission source. Accordingly, unnecessary vapor deposition particles that remain inside the at least one common pipe and inside the at least one vapor deposition particle emission source can be evacuated by the exhaust pump, and vapor deposition particles from each of the vapor deposition sources can be emitted independent of each other from the at least one vapor deposition particle emission source. Accordingly, vapor deposition particles from each of the vapor deposition sources can be emitted at a stable vapor deposition rate, and the ratio of concentration of vapor deposition particles from the vapor deposition sources can be set to a predetermined value. As a result, unlike the conventional example described above, even in the case of performing co-deposition of two or more types of materials, a co-deposition film can be formed precisely.

Also, in the above vapor deposition device, included among the plurality of vapor deposition sources may be a first vapor deposition source that produces vapor deposition particles of a host material and a second vapor deposition source that produces vapor deposition particles of a dopant material, and

the vapor deposition particles of the host material from the first vapor deposition source and the vapor deposition particles of the dopant material from the second vapor deposition source may be alternatingly passed through the one common pipe and emitted from the one vapor deposition particle emission source.

In this case, vapor deposition particles of the host material and vapor deposition particles of the dopant material can be alternatingly emitted from the one vapor deposition particle emission source, thus making it possible to precisely form the host material layer made up of vapor deposition particles of the host material and the dopant material layer made up of vapor deposition particles of the dopant material, and making it possible to also precisely form a co-deposition film that is made up of the host material layer and the dopant material layer.

Also, in the above vapor deposition device, it is preferable that the first vapor deposition source is connected to the one common pipe via a first switching valve,

the second vapor deposition source is connected to the one common pipe via a second switching valve,

a first exhaust pump for evacuating the vapor deposition particles of the host material from the first vapor deposition source is connected to the first switching valve, and

a second exhaust pump for evacuating the vapor deposition particles of the dopant material from the second vapor deposition source is connected to the second switching valve.

In this case, the first and second vapor deposition sources always operate at the same time, and vapor deposition particles of the host material and vapor deposition particles of the dopant material can be emitted alternatingly. As a result, the vapor deposition rate of vapor deposition particles of the host material and the dopant material can be controlled easily, and a high-quality co-deposition film can be formed easily.

Also, in the above vapor deposition device, included among the plurality of vapor deposition sources may be a first vapor deposition source that produces vapor deposition particles of a host material, a second vapor deposition source that produces vapor deposition particles of a dopant material, and a third vapor deposition source that produces vapor deposition particles of an assist material, and

the vapor deposition particles of the host material from the first vapor deposition source, the vapor deposition particles of the dopant material from the second vapor deposition source, and the vapor deposition particles of the assist material from the third vapor deposition source may be successively passed through the one common pipe and emitted from the one vapor deposition particle emission source.

In this case, vapor deposition particles of the host material, vapor deposition particles of the dopant material, and vapor deposition particles of the assist material can be successively emitted from the one vapor deposition particle emission source, thus making it possible to precisely form the host material layer made up of vapor deposition particles of the host material, the dopant material layer made up of vapor deposition particles of the dopant material, and the assist material layer made up of vapor deposition particles of the assist material, and making it possible to also precisely form a co-deposition film that is made up of the host material layer, the dopant material layer, and the assist material layer.

Also, in the above vapor deposition device, it is preferable that the first vapor deposition source is connected to the one common pipe via a first switching valve,

the second vapor deposition source is connected to the one common pipe via a second switching valve,

the third vapor deposition source is connected to the one common pipe via a third switching valve,

a first exhaust pump for evacuating the vapor deposition particles of the host material from the first vapor deposition source is connected to the first switching valve,

a second exhaust pump for evacuating the vapor deposition particles of the dopant material from the second vapor deposition source is connected to the second switching valve, and

a third exhaust pump for evacuating the vapor deposition particles of the assist material from the third vapor deposition source is connected to the third switching valve.

In this case, the first, second, and third vapor deposition sources always operate at the same time, and vapor deposition particles of the host material, vapor deposition particles of the dopant material, and vapor deposition particles of the assist material can be emitted successively. As a result, the vapor deposition rate of vapor deposition particles of the host material, the dopant material, and the assist material can be controlled easily, and a high-quality co-deposition film can be formed easily.

Also, in the above vapor deposition device, included among the plurality of vapor deposition sources may be a first vapor deposition source that produces vapor deposition particles of a host material and a second vapor deposition source that produces vapor deposition particles of a dopant material,

first, second, third, and fourth common pipes may be provided as the at least one common pipe,

first, second, third, and fourth vapor deposition particle emission sources that are respectively connected to the first, second, third, and fourth common pipes may be provided as the at least one vapor deposition particle emission source,

first, second, third, and fourth exhaust valves that are respectively connected to the first, second, third, and fourth vapor deposition particle emission sources may be provided as the exhaust valve,

the first vapor deposition source may be connected to the first and second common pipes via first and third switching valves, and the first vapor deposition source may be connected to the third and fourth common pipes via first and fourth switching valves, and

the second vapor deposition source may be connected to the first and second common pipes via second and fifth switching valves, and the second vapor deposition source may be connected to the third and fourth common pipes via second and sixth switching valves.

In this case, even when the first and second vapor deposition sources always operate at the same time, vapor deposition particles of the host material and the dopant material can be separately emitted from respective vapor deposition particle emission sources among the first to fourth vapor deposition particle emission sources. As a result, the utilization efficiency of the vapor deposition particles can be improved, and a co-deposition film can be formed with a higher yield.

Also, in the above vapor deposition device, it is preferable that one exhaust pump is connected to the first, second, third, and fourth exhaust valves.

In this case, the device configuration can be simplified in comparison to the case where an exhaust pump is provided for each of the first to fourth exhaust valves.

Also, in the above vapor deposition device, it is preferable that a rate monitor is provided between the at least one common pipe and each of the vapor deposition sources, and each rate monitor monitors a production amount of vapor deposition particles from the corresponding vapor deposition source.

In this case, the production rate of vapor deposition particles can be monitored by the rate monitors, thus making it possible to form a co-deposition film even more precisely.

Also, in the above vapor deposition device, it is preferable that a crucible and a heater that heats the interior of the crucible are included in each of the vapor deposition sources.

In this case, vapor deposition particles can be produced efficiently.

Also, a vapor deposition method according to the present invention is a vapor deposition method of performing a vapor deposition step of forming a film by depositing vapor deposition particles onto a substrate with use of a vapor deposition device that includes a plurality of vapor deposition sources, at least one common pipe that is connected to the plurality of vapor deposition sources, at least one vapor deposition particle emission source that is connected to the at least one common pipe and emits vapor deposition particles from each of the vapor deposition sources, an exhaust valve that is connected to the at least one vapor deposition particle emission source, and an exhaust pump that is connected to the exhaust valve,

wherein in the vapor deposition step, a host material layer made up of vapor deposition particles of a host material and a dopant material layer made up of vapor deposition particles of a dopant material are vapor deposited by alternatingly operating first and second switching valves respectively connected to first and second vapor deposition sources so as to alternatingly connect the first and second vapor deposition sources to one common pipe.

In the vapor deposition method having the above configuration, unnecessary vapor deposition particles that remain inside the at least one common pipe and inside the at least one vapor deposition particle emission source can be evacuated by the exhaust pump, and vapor deposition particles from each of the vapor deposition sources can be emitted independent of each other from the at least one vapor deposition particle emission source. Accordingly, vapor deposition particles from each of the vapor deposition sources can be emitted at a stable vapor deposition rate, and the ratio of concentration of vapor deposition particles from the vapor deposition sources can be set to a predetermined value. As a result, unlike the conventional example described above, even in the case of performing co-deposition of two or more types of materials, a co-deposition film that is the aforementioned film can be formed precisely.

Also, in the above vapor deposition method, in the vapor deposition step, a host material layer formation step of forming the host material layer and a dopant material layer formation step of forming the dopant material layer may be performed successively,

in the host material layer formation step,

a mid-vapor deposition step may be a step in which

the first and second vapor deposition sources operate at the same time,

the first switching valve connects the first vapor deposition source to the one common pipe,

the second switching valve connects the second vapor deposition source to a second exhaust pump,

the exhaust valve is closed, and

the second exhaust pump operates, and

a post-vapor deposition step may be a step in which

the first and second vapor deposition sources operate at the same time,

the first switching valve connects the first vapor deposition source to a first exhaust pump,

the second switching valve connects the second vapor deposition source to the second exhaust pump,

the exhaust valve is open, and

the first and second exhaust pumps and the exhaust pump operate, and

in the dopant material layer formation step,

a mid-vapor deposition step may be a step in which

the first and second vapor deposition sources operate at the same time,

the first switching valve connects the first vapor deposition source to the first exhaust pump,

the second switching valve connects the second vapor deposition source to the one common pipe,

the exhaust valve is closed, and

the first exhaust pump operates, and

a post-vapor deposition step may be a step in which

the first and second vapor deposition sources operate at the same time,

the first switching valve connects the first vapor deposition source to the first exhaust pump,

the second switching valve connects the second vapor deposition source to the second exhaust pump,

the exhaust valve is open, and

the first and second exhaust pumps and the exhaust pump operate.

In this case, the first and second vapor deposition sources always operate at the same time, and vapor deposition particles of the host material and vapor deposition particles of the dopant material can be emitted alternatingly. As a result, the vapor deposition rate of vapor deposition particles of the host material and the dopant material can be controlled easily, and a high-quality co-deposition film can be formed easily.

Also, in the above vapor deposition method, in the vapor deposition step, a host material layer formation step of forming the host material layer, a dopant material layer formation step of forming the dopant material layer, and an assist material layer formation step of forming an assist material layer made up of vapor deposition particles of an assist material may be performed successively,

in the host material layer formation step,

a mid-vapor deposition step may be a step in which

the first and second vapor deposition sources and a third vapor deposition source operate at the same time,

the first switching valve connects the first vapor deposition source to the one common pipe,

the second switching valve connects the second vapor deposition source to a second exhaust pump,

a third switching valve connects the third vapor deposition source to a third exhaust pump,

the exhaust valve is closed, and

the second and third exhaust pumps operate, and

a post-vapor deposition step may be a step in which

the first, second, and third vapor deposition sources operate at the same time,

the first switching valve connects the first vapor deposition source to a first exhaust pump,

the second switching valve connects the second vapor deposition source to the second exhaust pump,

the third switching valve connects the third vapor deposition source to the third exhaust pump,

the exhaust valve is open, and

the first, second, and third exhaust pumps and the exhaust pump operate,

in the dopant material layer formation step,

a mid-vapor deposition step may be a step in which

the first, second, and third vapor deposition sources operate at the same time,

the first switching valve connects the first vapor deposition source to the first exhaust pump,

the second switching valve connects the second vapor deposition source to the one common pipe,

the third switching valve connects the third vapor deposition source to the third exhaust pump,

the exhaust valve is closed, and

the first and third exhaust pumps operate, and

a post-vapor deposition step may be a step in which

the first, second, and third vapor deposition sources operate at the same time,

the first switching valve connects the first vapor deposition source to the first exhaust pump,

the second switching valve connects the second vapor deposition source to the second exhaust pump,

the third switching valve connects the third vapor deposition source to the third exhaust pump,

the exhaust valve is open, and

the first, second, and third exhaust pumps and the exhaust pump operate, and

in the assist material layer formation step,

a mid-vapor deposition step may be a step in which

the first, second, and third vapor deposition sources operate at the same time,

the first switching valve connects the first vapor deposition source to the first exhaust pump,

the second switching valve connects the second vapor deposition source to the second exhaust pump,

the third switching valve connects the third vapor deposition source to the one common pipe,

the exhaust valve is closed, and

the first and second exhaust pumps operate, and

a post-vapor deposition step may be a step in which

the first, second, and third vapor deposition sources operate at the same time,

the first switching valve connects the first vapor deposition source to the first exhaust pump,

the second switching valve connects the second vapor deposition source to the second exhaust pump,

the third switching valve connects the third vapor deposition source to the third exhaust pump,

the exhaust valve is open, and

the first, second, and third exhaust pumps and the exhaust pump operate.

In this case, the first, second, and third vapor deposition sources always operate at the same time, and vapor deposition particles of the host material, vapor deposition particles of the dopant material, and vapor deposition particles of the assist material can be emitted successively. As a result, the vapor deposition rate of vapor deposition particles of the host material, the dopant material, and the assist material can be controlled easily, and a high-quality co-deposition film can be formed easily.

Also, in the above vapor deposition method, the vapor deposition step may include

a first sub vapor deposition step in which the vapor deposition particles of the host material from the first vapor deposition source are emitted from the first vapor deposition particle emission source, and the vapor deposition particles of the dopant material from the second vapor deposition source are emitted from the fourth vapor deposition particle emission source,

a second sub vapor deposition step in which the vapor deposition particles of the host material from the first vapor deposition source are emitted from the second vapor deposition particle emission source, and the vapor deposition particles of the dopant material from the second vapor deposition source are emitted from the third vapor deposition particle emission source,

a third sub vapor deposition step in which the vapor deposition particles of the host material from the first vapor deposition source are emitted from the fourth vapor deposition particle emission source, and the vapor deposition particles of the dopant material from the second vapor deposition source are emitted from the first vapor deposition particle emission source, and

a fourth sub vapor deposition step in which the vapor deposition particles of the host material from the first vapor deposition source are emitted from the third vapor deposition particle emission source, and the vapor deposition particles of the dopant material from the second vapor deposition source are emitted from the second vapor deposition particle emission source.

In this case, even when the first and second vapor deposition sources always operate at the same time, vapor deposition particles of the host material and the dopant material can be separately emitted from respective vapor deposition particle emission sources among the first to fourth vapor deposition particle emission sources. As a result, the utilization efficiency of the vapor deposition particles can be improved, and a co-deposition film can be formed with a higher yield.

Also, in the above vapor deposition method, a control plate may be formed between the substrate and each pair of adjacent vapor deposition particle emission sources among the first to fourth vapor deposition particle emission sources, and

in the first, second, third, and fourth sub vapor deposition steps, the vapor deposition particles of the host material and the vapor deposition particles of the dopant material may be emitted so as to not be overlapped on the substrate.

In this case, the utilization efficiency of vapor deposition particles of the host material and the dopant material can be improved, and a co-deposition film that is a laminate structure made up of the host material layer and the dopant material layer can be formed with a higher yield.

Also, in the above vapor deposition method, in the first, second, third, and fourth sub vapor deposition steps, the vapor deposition particles of the host material and the vapor deposition particles of the dopant material may be emitted so as to be overlapped on the substrate.

In this case, a co-deposition film in which vapor deposition particles of the host material and vapor deposition particles of the dopant material are mixed can be formed efficiently, and a more homogenous co-deposition film can be formed.

Also, an organic EL element according to the present invention has the film formed using any of the vapor deposition methods.

In the organic EL element configured as described above, the film is constituted by a precisely formed co-deposition film, thus making it possible to easily configure a high-quality organic EL element.

Also, in the above organic EL element, it is preferable that the film is a light emitting layer.

In this case, it is possible to easily configure an organic EL element that includes a light emitting layer that has superior characteristics.

Also, in the above organic EL element, it is preferable that the film is a hole injection layer.

In this case, it is possible to easily configure an organic EL element that includes a hole injection layer that has superior characteristics.

According to the present invention, it is possible to provide a vapor deposition device and a vapor deposition method that, even when performing co-deposition of two or more types of materials, can precisely form a co-deposition film, and an organic EL element using the same.

### BRIEF DESCRIPTION OF DRAWINGS

FIG. 1 is a cross-sectional diagram showing a configuration of an organic EL element according to a first embodiment of the present invention.

FIG. 2 is a diagram illustrating a vapor deposition device according to the first embodiment of the present invention.

FIG. 3 is a flowchart illustrating a vapor deposition method according to the first embodiment of the present invention.

FIG. 4 is a diagram illustrating an operation state of the vapor deposition device in a host material layer formation step shown in FIG. 3.

FIG. 5 is a diagram illustrating an operation state of the vapor deposition device in a dopant material layer material formation step shown in FIG. 3.

FIG. 6 is a cross-sectional diagram showing a configuration of an organic EL element according to a second embodiment of the present invention.

FIG. 7 is a diagram illustrating a vapor deposition device according to the second embodiment of the present invention.

FIG. 8 is a flowchart illustrating a vapor deposition method according to the second embodiment of the present invention.

FIG. 9 is a diagram illustrating an operation state of the vapor deposition device shown in FIG. 7 in a host material layer formation step shown in FIG. 8.

FIG. 10 is a diagram illustrating an operation state of the vapor deposition device shown in FIG. 7 in a dopant material layer material formation step shown in FIG. 8.

FIG. 11 is a diagram illustrating an operation state of the vapor deposition device shown in FIG. 7 in an assist material layer material formation step shown in FIG. 8.

FIG. 12 is a diagram illustrating a vapor deposition device according to a third embodiment of the present invention.

FIG. 13 is a flowchart illustrating a vapor deposition method according to the third embodiment of the present invention.

FIG. 14 is a diagram illustrating an operation state of the vapor deposition device shown in FIG. 12 in a first sub vapor deposition step shown in FIG. 13.

FIG. 15 is a diagram illustrating an operation state of the vapor deposition device shown in FIG. 12 in a second sub vapor deposition step shown in FIG. 13.

FIG. 16 is a diagram illustrating an operation state of the vapor deposition device shown in FIG. 12 in a third sub vapor deposition step shown in FIG. 13.

FIG. 17 is a diagram illustrating an operation state of the vapor deposition device shown in FIG. 12 in a fourth sub vapor deposition step shown in FIG. 13.

FIG. 18 is a cross-sectional diagram showing a configuration of an organic EL element according to a fourth embodiment of the present invention.

FIG. 19 is a diagram illustrating a vapor deposition device according to the fourth embodiment of the present invention.

FIG. 20 is a diagram illustrating an operation state of the vapor deposition device shown in FIG. 19 in the first sub vapor deposition step.

FIG. 21 is a diagram illustrating an operation state of the vapor deposition device shown in FIG. 19 in the second sub vapor deposition step.

FIG. 22 is a diagram illustrating an operation state of the vapor deposition device shown in FIG. 19 in the third sub vapor deposition step.

FIG. 23 is a diagram illustrating an operation state of the vapor deposition device shown in FIG. 19 in the fourth sub vapor deposition step.

FIG. 24 is a diagram illustrating a conventional vapor deposition device.

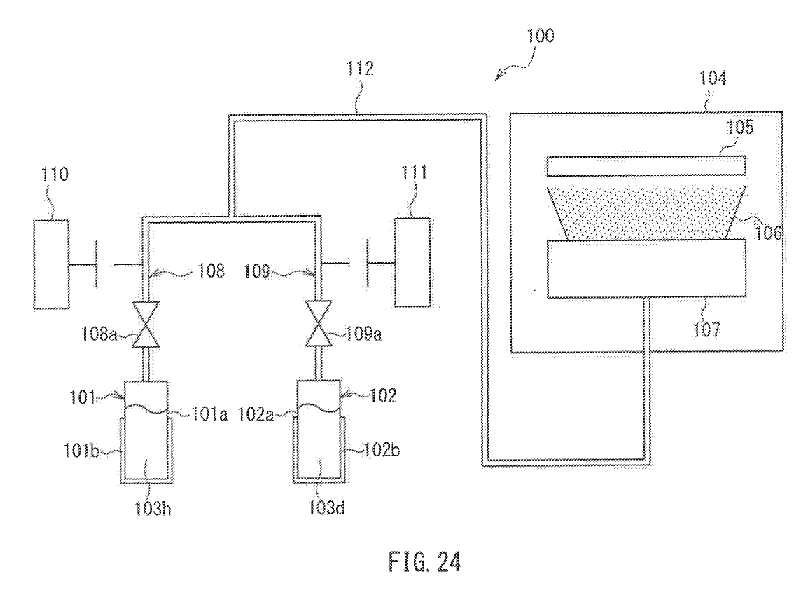

### DETAILED DESCRIPTION OF THE INVENTION

Hereinafter, preferred embodiments of a vapor deposition device, a vapor deposition method, and an organic EL element of the present invention will be described with reference to the drawings. Note that in the following description, the dimensions of constituent members in the drawings are not faithful representations of the dimensions of actual constituent members, the dimensional proportions of constituent members, and the like.

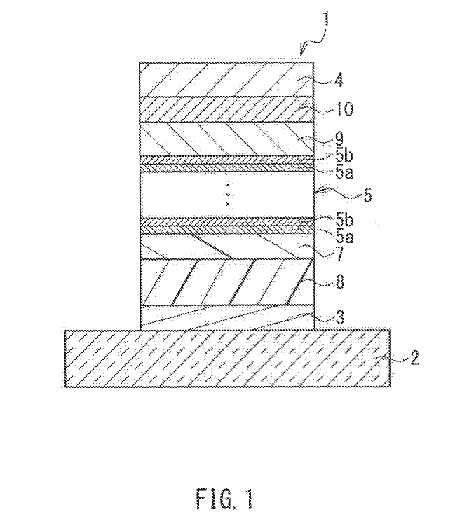

FIG. 1 is a cross-sectional diagram showing the configuration of an organic EL element according to a first embodiment of the present invention. In FIG. 1, an organic EL element 1 of the present embodiment includes a substrate 2, an anode 3 provided on the substrate 2, and a cathode 4 provided above the anode 3. Also, in the organic EL element 1, a light emitting layer 5, which is a film, is provided between the anode 3 and the cathode 4. Moreover, in the organic EL element 1, a hole transport layer 7 and a hole injection layer 8 are provided between the anode 3 and the light emitting layer 5 in the stated order from the light emitting layer 5 toward the anode 3. Furthermore, in the organic EL element 1, an electron transport layer 9 and an electron injection layer 10 are provided between the cathode 4 and the light emitting layer 5 in the stated order from the light emitting layer 5 toward the cathode 4.

The substrate 2 is made of a material such as glass. The anode 3 is made of a transparent electrode material such as ITO. Also, the thickness of this anode 3 is approximately 20 nm to 100 nm, for example.

The cathode 4 is made of aluminum, silver, or the like. Also, although the thickness of the cathode 4 can be set freely, generally it is preferably approximately several nm to 30 nm in the case of a top emission structure in which light is extracted on the cathode 4 side, for example. Also, this thickness may be several tens of nm in the case of a bottom emission structure in which light is extracted on the substrate 2 side. Moreover, it may be made of a transparent electrode material such as ITO or IZO.

The light emitting layer 5 is formed by a later-described vapor deposition device of the present embodiment, and is constituted by a laminate structure (co-deposition film) obtained by alternatingly laminating a host material layer 5a made up of vapor deposition particles of a host material and a dopant material layer 5b made up of vapor deposition particles of a dopant material (guest compound) (This will be described in detail later.).

The hole transport layer of an ordinary organic EL element for example can be used for the hole transport layer 7, and one example is 4,4′-bis[N-(1-naphthyl)-N-phenyl-amino]-biphenyl (α-NPD). Also, the thickness of this hole transport layer 7 is 15 nm, for example.

The hole injection layer 8 is made of a phthalocyanine-based material, a starburst polyamine, a polyaniline, or the like. The thickness of this hole injection layer 8 is several tens of nm, for example.

The electron transport layer 9 is made of BPhen or the like. Also, the thickness of this electron transport layer 9 is 20 nm, for example.

The electron injection layer 10 is made of metallic lithium, metallic barium, or the like, or a compound thereof such as lithium fluoride. Also, the thickness of this electron injection layer 10 is often very low, such as 0.1 nm.

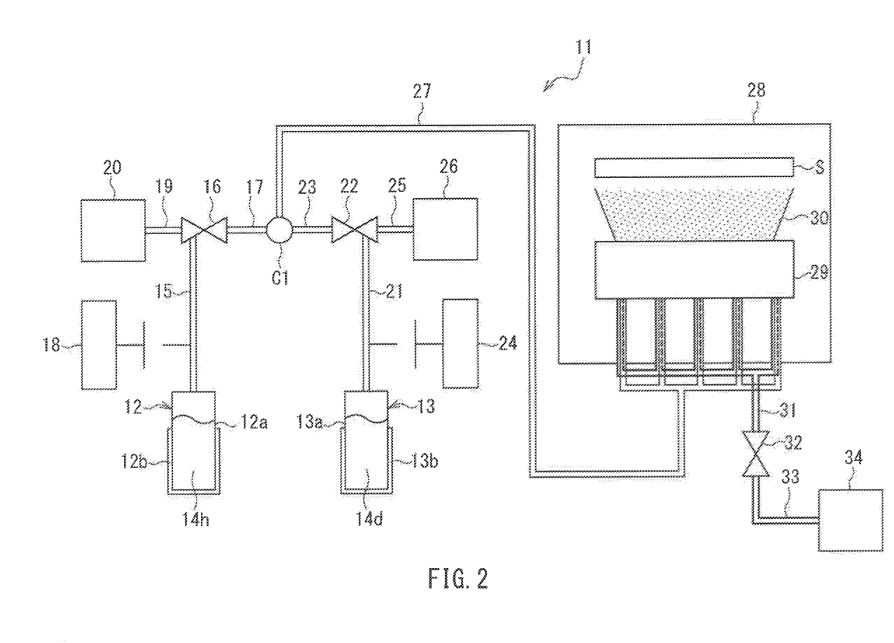

Next, a vapor deposition device 11 of the present embodiment will be described in detail with reference to FIG. 2.

FIG. 2 is a diagram illustrating the vapor deposition device according to the first embodiment of the present invention.

In FIG. 2, the vapor deposition device 11 of the present embodiment includes a first vapor deposition source 12 that produces vapor deposition particles of a host material 14h, and a second vapor deposition source 13 that produces vapor deposition particles of a dopant material 14d.

The first vapor deposition source 12 includes a crucible 12a into which the host material 14h is placed, and a heater 12b that is provided around the crucible 12a and heats the interior of the crucible 12a, and the first vapor deposition source 12 can efficiently produce vapor deposition particles of the host material 14h.

Similarly, the second vapor deposition source 13 includes a crucible 13a into which the dopant material 14d is placed, and a heater 13b that is provided around the crucible 13a and heats the interior of the crucible 13a, and the second vapor deposition source 13 can efficiently produce vapor deposition particles of the dopant material 14d.

Also, the host material 14h is made of CBP (4,4′-bis[9-discarbazolyl]-2,2′-biphenyl) or TCTA (4,4′,4″-tris(N-carbazolyl)triphenylamine), for example. Moreover, in the case of configuring red, green, and blue light emitting layers, the dopant material 14d is made of Ir(pic)₃ for red phosphorescence, Ir(ppy)₃ for green phosphorescence, and FIrpic for blue phosphorescence, for example. Furthermore, the film thickness of the light emitting layer 5 is 300 Å, for example.

Also, the first vapor deposition source 12 is connected to one common pipe 27 as the at least one common pipe via a first switching valve 16, and the second vapor deposition source 13 is connected to the common pipe 27 via a second switching valve 22.

Specifically, one end of a pipe 15 is connected to the first switching valve 16, and the other end is connected to the first vapor deposition source 12. Also, the first switching valve 16 is connected to a junction point C1, which is one end portion of the common pipe 27, via a pipe 17, and the first switching valve 16 is also connected to a first exhaust pump 20 via a pipe 19. Furthermore, the first switching valve 16 is configured to appropriately switch between putting the pipe 15 and the pipe 17 into communication and putting the pipe 15 and the pipe 19 into communication.

Also, the pipe 15 is provided with a rate monitor 18 that monitors the production amount (vapor deposition density) of vapor deposition particles of the host material 14h from the first vapor deposition source 12. Accordingly, with the vapor deposition device 11 of the present embodiment, the host material layer 5a can be formed more precisely, and therefore the light emitting layer (co-deposition film) 5 can also be formed more precisely.

Also, one end of a pipe 21 is connected to the second switching valve 22, and the other end is connected to the second vapor deposition source 13. Also, the second switching valve 22 is connected to the junction point C1 (one end portion of the common pipe 27) via a pipe 23, and the second switching valve 22 is also connected to a second exhaust pump 26 via a pipe 25. Furthermore, the second switching valve 22 is configured to appropriately switch between putting the pipe 21 and the pipe 23 into communication and putting the pipe 21 and the pipe 25 into communication.

Also, the pipe 21 is provided with a rate monitor 24 that monitors the production amount (vapor deposition density) of vapor deposition particles of the dopant material 14d from the second vapor deposition source 13. Accordingly, with the vapor deposition device 11 of the present embodiment, the dopant material layer 5b can be formed more precisely, and therefore the light emitting layer (co-deposition film) 5 can also be formed more precisely.

Also, multiple branch pipes, which are branched into multiple paths, are provided at the other end portion of the common pipe 27, and the branch pipes are connected to a vapor deposition particle emission source 29 provided in the vacuum chamber 28. Also, the vapor deposition particle emission source 29 has a hole portion (not shown) for emitting vapor deposition particles, and is connected to an exhaust valve 32 via a pipe 31. Also, this exhaust valve 32 is connected to an exhaust pump 34 via a pipe 33.

Also, in the vapor deposition device 11 of the present embodiment, the first and second vapor deposition sources 12 and 13 are operated at the same time, and by appropriately operating the first and second switching valves 16 and 22, vapor deposition particles of the host material 14h and vapor deposition particles of the dopant material 14d from the first and second vapor deposition sources 12 and 13 are alternatingly allowed to flow one at a time into the common pipe 27 via the corresponding one of the first and second switching valves 16 and 22. Also, in the vapor deposition device 11 of the present embodiment, vapor deposition particles of the host material 14h and vapor deposition particles of the dopant material 14d are alternatingly fed from the common pipe 27 into the vapor deposition particle emission source 29, and then emitted from the vapor deposition particle emission source 29 as vapor deposition particles 30 bound for a substrate S.

Also, the vapor deposition device 11 of the present embodiment is a cluster type of device for vapor depositing the above-described vapor deposition particles on one substrate S inside the vacuum chamber 28, and, furthermore, the vapor deposition device 11 of the present embodiment constitutes a scanning vapor deposition device in which a mask (not shown) for forming the light emitting layer 5 in a predetermined pattern is provided between the vapor deposition particle emission source 29 and the substrate S, and in which the substrate S and the mask move along directions perpendicular to the paper surface of FIG. 2 when the vapor deposition particles are emitted from the vapor deposition particle emission source 29. Accordingly, the light emitting layer 5, which is a film in a predetermined pattern, is formed on the substrate S.

Also, the vapor deposition device 11 of the present embodiment is configured such that when the emission of vapor deposition particles of the host material 14h or vapor deposition particles of the dopant material 14d onto the substrate S has ended, the exhaust pump 34 evacuates the vapor deposition particles.

Specifically, when the emission of vapor deposition particles of the host material 14h has ended, the exhaust pump 34 evacuates vapor deposition particles of the host material 14h that exist inside the pipe 17 (including the pipe 17 side of the inside of the first switching valve 16 as well), inside the pipe 23 (including the pipe 23 side of the inside of the second switching valve 22 as well), inside the common pipe 27, and inside the vapor deposition particle emission source 29, to the outside via the pipe 31, the exhaust valve 32, and the pipe 33.

Also, when the emission of vapor deposition particles of the dopant material 14d has ended, the exhaust pump 34 evacuates vapor deposition particles of the dopant material 14d that exist inside the pipe 17 (including the pipe 17 side of the inside of the first switching valve 16 as well), inside the pipe 23 (including the pipe 23 side of the inside of the second switching valve 22 as well), inside the common pipe 27, and inside the vapor deposition particle emission source 29, to the outside via the pipe 31, the exhaust valve 32, and the pipe 33.

Also, in the vapor deposition device 11 of the present embodiment, the first and second vapor deposition sources 12 and 13 are operated at the same time and respectively produce vapor deposition particles of the host material 14h and vapor deposition particles of the dopant material 14d, and therefore when vapor deposition particles of the host material 14h are allowed to flow into the common pipe 27, the second exhaust valve 26 evacuates the vapor deposition particles of the dopant material 14d from the second vapor deposition source 13 to the outside via the pipe 25. Also, when vapor deposition particles of the dopant material 14d are allowed to flow into the common pipe 27, the first exhaust valve 20 evacuates the vapor deposition particles of the host material 14h from the first vapor deposition source 12 to the outside via the pipe 19.

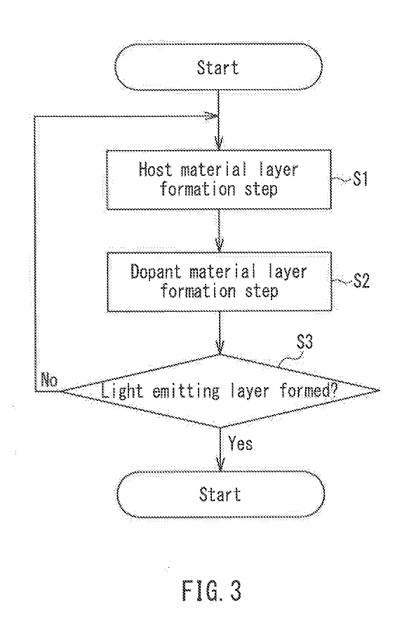

Next, a vapor deposition method performed by the vapor deposition device 11 of the present embodiment will be described in detail with reference to FIGS. 3 to 5 as well.

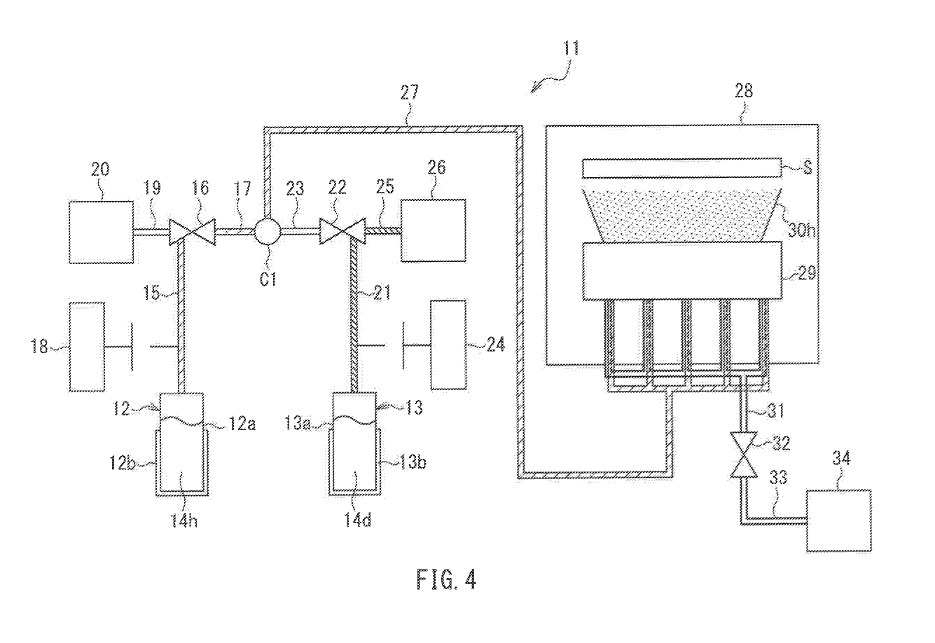

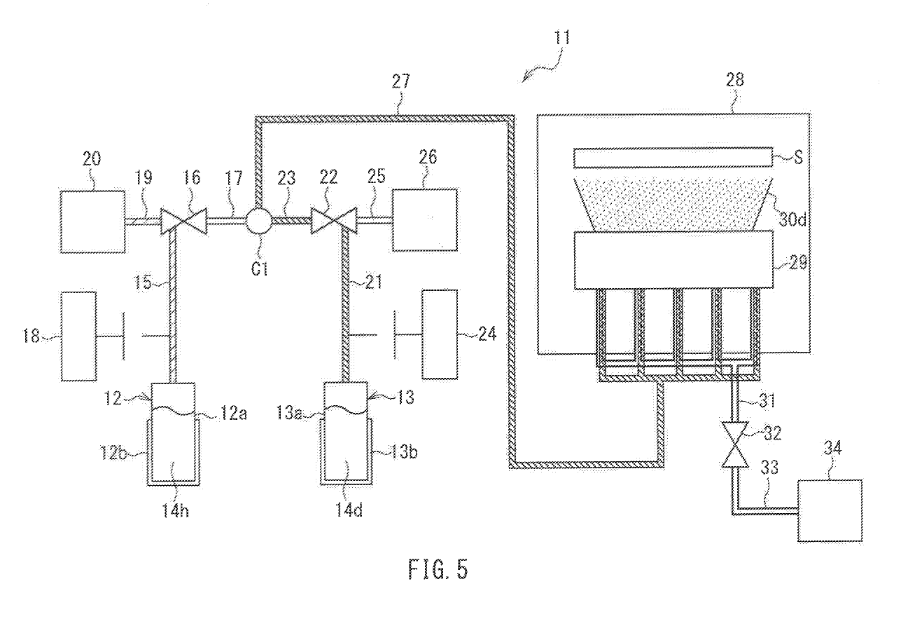

FIG. 3 is a flowchart illustrating the vapor deposition method according to the first embodiment of the present invention. FIG. 4 is a diagram illustrating an operation state of the vapor deposition device in a host material layer formation step shown in FIG. 3. FIG. 5 is a diagram illustrating an operation state of the vapor deposition device in a dopant material layer material formation step shown in FIG. 3.

As shown in step S1 in FIG. 3, in the present embodiment, first, a host material layer formation step of forming the host material layer 5a on the substrate S is performed.

Specifically, this host material layer formation step is divided into a mid-vapor deposition step of vapor depositing vapor deposition particles of the host material 14h and a post-vapor deposition step performed thereafter.

In the mid-vapor deposition step of vapor depositing vapor deposition particles of the host material 14h, the first and second vapor deposition sources 12 and 13 are operated at the same time, and vapor deposition particles of the host material 14h and vapor deposition particles of the dopant material 14d are produced.

Also, the junction point C1 side of the first switching valve 16 is opened, and the first switching valve 16 connects the first vapor deposition source 12 and the (one) common pipe 27. Also, the second exhaust pump 26 side of the second switching valve 22 is opened, and the second switching valve 22 connects the second vapor deposition source 13 and the second exhaust pump 26. Also, the exhaust valve 32 is closed. Furthermore, the second exhaust pump 26 operates.

Accordingly, in this mid-vapor deposition step, vapor deposition particles of the host material 14h pass through the pipe 15, the pipe 17, the junction point C1, and the common pipe 27 as shown by the left-downward diagonal hatching in FIG. 4, and are emitted as vapor deposition particles 30h from the vapor deposition particle emission source 29. As a result, the host material layer 5a is formed on the substrate S. Meanwhile, vapor deposition particles of the dopant material 14d pass through the pipe 21 and the pipe 25 as shown by the right-downward diagonal hatching in FIG. 4, and are evacuated by the second exhaust pump 26. Note that in this mid-vapor deposition step, the first exhaust pump 20 and the exhaust pump 34 are put in the on (operating) state or off (stopped) state.

Next, in the post-vapor deposition step, the first and second vapor deposition sources 12 and 13 are operated at the same time. Also, the first exhaust pump 20 side of the first switching valve 16 is opened, and the first switching valve 16 connects the first vapor deposition source 12 and the first exhaust pump 20. Also, the second exhaust pump 26 side of the second switching valve 22 is opened, and the second switching valve 22 connects the second vapor deposition source 13 and the second exhaust pump 26. Also, the exhaust valve 32 is opened. Furthermore, the first and second exhaust pumps 20 and 26 and the exhaust pump 34 operate.

Accordingly, in this post-vapor deposition step, the first exhaust pump 20 evacuates vapor deposition particles of the host material 14h that exist inside the pipe 15 and inside the pipe 19 (including the pipe 19 side of the inside of the first switching valve 16). In other words, vapor deposition particles of the host material 14h from the first vapor deposition source 12 are evacuated by the first exhaust pump 20.

Also, the second exhaust pump 26 evacuates vapor deposition particles of the dopant material 14d that exist inside the pipe 21 and inside the pipe 25 (including the pipe 25 side of the inside of the second switching valve 22). In other words, vapor deposition particles of the dopant material 14d from the second vapor deposition source 13 are evacuated by the second exhaust pump 26.

Furthermore, the exhaust pump 34 evacuates vapor deposition particles of the host material 14h that exist inside the pipe 17 (including the pipe 17 side of the first switching valve 16 as well), inside the pipe 23 (including the pipe 23 side of the inside of the second switching valve 22 as well), inside the common pipe 27, and inside the vapor deposition particle emission source 29.

Next, as shown in step S2 in FIG. 3, a dopant material layer formation step of forming the dopant material layer 5b is performed.

Specifically, this dopant material layer formation step is divided into a mid-vapor deposition step of vapor depositing vapor deposition particles of the dopant material 14d and a post-vapor deposition step performed thereafter.

In the mid-vapor deposition step of vapor depositing vapor deposition particles of the dopant material 14d, the first and second vapor deposition sources 12 and 13 are operated at the same time, and vapor deposition particles of the host material 14h and vapor deposition particles of the dopant material 14d are produced.

Also, the first exhaust pump 20 side of the first switching valve 16 is opened, and the first switching valve 16 connects the first vapor deposition source 12 and the first exhaust pump 20. Also, the junction point C1 side of the second switching valve 22 is opened, and the second switching valve 22 connects the second vapor deposition source 13 and the (one) common pipe 27. Also, the exhaust valve 32 is closed. Furthermore, the first exhaust pump 20 operates.

Accordingly, in this mid-vapor deposition step, vapor deposition particles of the dopant material 14d pass through the pipe 21, the pipe 23, the junction point C1, and the common pipe 27 as shown by the right-downward diagonal hatching in FIG. 5, and are emitted as vapor deposition particles 30d from the vapor deposition particle emission source 29. As a result, the dopant material layer 5b is formed on the substrate S. Meanwhile, vapor deposition particles of the host material 14h pass through the pipe 15 and the pipe 19 as shown by the left-downward diagonal hatching in FIG. 5, and are evacuated by the first exhaust pump 20. Note that in this mid-vapor deposition step, the second exhaust pump 26 and the exhaust pump 34 are put in the on (operating) state or off (stopped) state.

Next, in the post-vapor deposition step, the first and second vapor deposition sources 12 and 13 are operated at the same time. Also, the first exhaust pump 20 side of the first switching valve 16 is opened, and the first switching valve 16 connects the first vapor deposition source 12 and the first exhaust pump 20. Also, the second exhaust pump 26 side of the second switching valve 22 is opened, and the second switching valve 22 connects the second vapor deposition source 13 and the second exhaust pump 26. Also, the exhaust valve 32 is opened. Furthermore, the first and second exhaust pumps 20 and 26 and the exhaust pump 34 operate.

Accordingly, in this post-vapor deposition step, the first exhaust pump 20 evacuates vapor deposition particles of the host material 14h that exist inside the pipe 15 and inside the pipe 19 (including the pipe 19 side of the inside of the first switching valve 16). In other words, vapor deposition particles of the host material 14h from the first vapor deposition source 12 are evacuated by the first exhaust pump 20.

Also, the second exhaust pump 26 evacuates vapor deposition particles of the dopant material 14d that exist inside the pipe 21 and inside the pipe 25 (including the pipe 25 side of the inside of the second switching valve 22). In other words, vapor deposition particles of the dopant material 14d from the second vapor deposition source 13 are evacuated by the second exhaust pump 26.

Furthermore, the exhaust pump 34 evacuates vapor deposition particles of the dopant material 14d that exist inside the pipe 17 (including the pipe 17 side of the first switching valve 16 as well), inside the pipe 23 (including the pipe 23 side of the inside of the second switching valve 22 as well), inside the common pipe 27, and inside the vapor deposition particle emission source 29.

Next, as shown in step S3 in FIG. 3, it is determined whether or not the light emitting layer 5 was formed. In other words, it is determined whether the light emitting layer 5 was formed to a predetermined thickness (e.g., 300 Å), and the vapor deposition step is ended if it is determined that the light emitting layer 5 has been formed to the predetermined thickness. On the other hand, the procedure returns to step S1 if it is determined that the light emitting layer 5 has not been formed to the predetermined thickness.

Note that in the host material layer formation step, the host material 14h is vapor deposited at a rate of 3 Å/s for example. Also, in the dopant material layer formation step, the dopant material 14d is vapor deposited at a rate of 0.3 Å/s for example. Also, the switching intervals of the first and second switching valves 16 and 22 are 1 time per second for example.

In the vapor deposition device 11 of the present embodiment having the configuration described above, the first and second vapor deposition sources 12 and 13 are connected to one common pipe 27, and vapor deposition particles of the host material 14h from the first vapor deposition source 12 and vapor deposition particles of the dopant material 14d from the second vapor deposition source 13 are emitted from the one vapor deposition particle emission source 29 that is connected to the one common pipe 27. Also, the exhaust valve 32 and the exhaust pump 34 are connected to the one vapor deposition particle emission source 29. Accordingly, in the vapor deposition device 11 of the present embodiment, unnecessary vapor deposition particles that remain inside the one common pipe 27 and inside the vapor deposition particle emission source 29 can be evacuated by the exhaust pump 34, and vapor deposition particles of the host material 14h from the first vapor deposition source 12 and vapor deposition particles of the dopant material 14d from the second vapor deposition source 13 can be emitted independent of each other from the one vapor deposition particle emission source 29. Accordingly, vapor deposition particles of the host material 14h and vapor deposition particles of the dopant material 14d can be emitted at a stable vapor deposition rate, and the ratio of concentration of vapor deposition particles of the host material 14h from the first vapor deposition source 12 and vapor deposition particles of the dopant material 14d from the second vapor deposition source 13 can be set to a predetermined value. As a result, with the vapor deposition device 11 of the present embodiment, the light emitting layer (co-deposition film) 5 can be precisely formed even in the case of performing co-deposition of two or more types of materials, unlike in the conventional example described above.

Also, in the present embodiment, vapor deposition particles of the host material 14h and vapor deposition particles of the dopant material 14d are alternatingly emitted from the one vapor deposition particle emission source 29, thus making it possible to precisely form the host material layer 5a made up of vapor deposition particles of the host material 14h and the dopant material layer 5b made up of vapor deposition particles of the dopant material 14d, and making it possible to also precisely form the light emitting layer 5 that is made up of the host material layer 5a and the dopant material layer 5b.

Also, in the present embodiment, the light emitting layer (co-deposition film) 5 can be precisely formed by the one vapor deposition particle emission source 29, thus making it possible to easily simplify the configuration of the vapor deposition device 11. Also, because the configuration of the vapor deposition device 11 can be easily simplified in this way, it is possible to easily raise the processing margin, and also improve the production takt time of the organic EL element 1.

Also, the organic EL element 1 of the present embodiment has the light emitting layer 5, which is a film formed using the vapor deposition method performed by the vapor deposition device 11, thus making it possible to easily configure a high-quality organic EL element 1 that has a superior light emission characteristics.

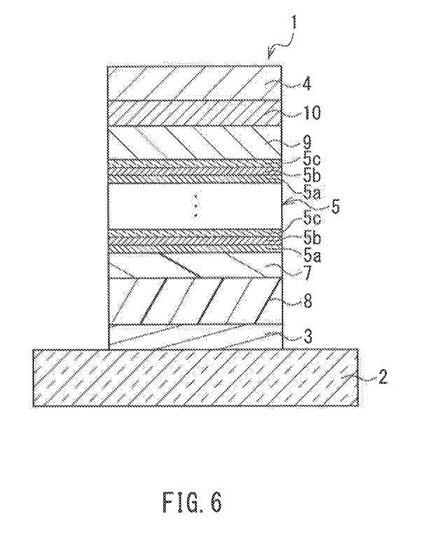

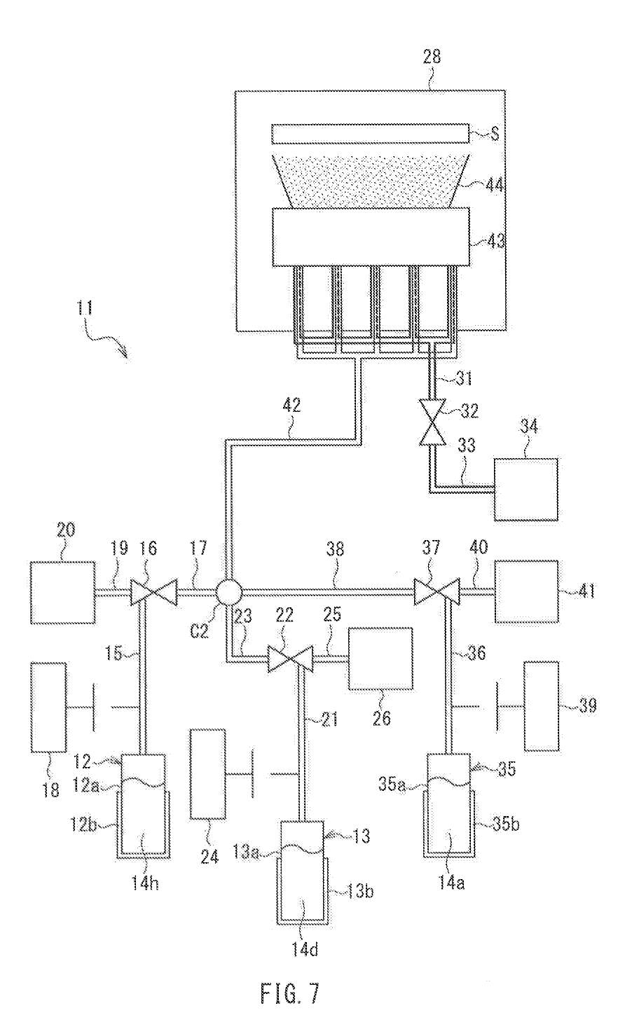

FIG. 6 is a cross-sectional diagram showing the configuration of an organic EL element according to a second embodiment of the present invention. FIG. 7 is a diagram illustrating the vapor deposition device according to the second embodiment of the present invention.

A main difference between the present embodiment and the first embodiment in this figure is that a third vapor deposition source for producing vapor deposition particles of an assist material is provided. Note that elements that are in common with the first embodiment are denoted by the same reference signs, and redundant descriptions will not be given for them.

Specifically, as shown in FIG. 6, in the organic EL element 1 of the present embodiment, the light emitting layer 5 thereof is constituted by a laminate structure (co-deposition film) obtained by successively laminating the host material layer 5a made up of vapor deposition particles of a host material, the dopant material layer 5b made up of vapor deposition particles of a dopant material (guest compound), and an assist material layer 5c made up of vapor deposition particles of an assist material (co-host material).

Also, as shown in FIG. 7, the vapor deposition device 11 of the present embodiment is provided with a third vapor deposition source 35 for producing vapor deposition particles of an assist material 14a.

This third vapor deposition source 35 includes a crucible 35a into which the assist material 14a is placed, and a heater 35b that is provided around the crucible 35a and heats the interior of the crucible 35a, and the third vapor deposition source 35 can efficiently produce vapor deposition particles of the assist material 14a.

Also, the assist material 14a is made up of TPBI (2,2′,2″-(1,3,5-benzenetriylltris(1-phenyl-1H-benzimidazole)), for example.

Also, the third vapor deposition source 35 is connected to one common pipe 42 as the at least one common pipe via a third switching valve 37. Specifically, one end of a pipe 36 is connected to the third switching valve 37, and the other end is connected to the third vapor deposition source 35. Also, the third switching valve 37 is connected to a junction point C2, which is one end portion of the common pipe 42, via a pipe 38, and the third switching valve 37 is also connected to a third exhaust pump 41 via a pipe 40. Furthermore, the third switching valve 37 is configured to appropriately switch between putting the pipe 36 and the pipe 38 into communication and putting the pipe 36 and the pipe 40 into communication.

Also, pipes 17 and 23 are connected to the junction point C2, and vapor deposition particles of the host material 14h from the first vapor deposition source 12 and vapor deposition particles of the dopant material 14d from the second vapor deposition source 13 can flow into the common pipe 42.

Also, the pipe 36 is provided with a rate monitor 39 that monitors the production amount (vapor deposition density) of vapor deposition particles of the assist material 14a from the third vapor deposition source 35. Accordingly, with the vapor deposition device 11 of the present embodiment, the assist material layer 5c can be formed more precisely, and therefore the light emitting layer (co-deposition film) 5 can also be formed more precisely.

Also, multiple branch pipes, which are branched into multiple paths, are provided at the other end portion of the common pipe 42, and the branch pipes are connected to a vapor deposition particle emission source 43 provided in the vacuum chamber 28. Also, similarly to the vapor deposition particle emission source of the first embodiment, this vapor deposition particle emission source 43 has a hole portion (not shown) for emitting vapor deposition particles, and is connected to the exhaust valve 32 via the pipe 31, and this exhaust valve 32 is connected to the exhaust pump 34 via the pipe 33.

Also, in the vapor deposition device 11 of the present embodiment, the first, second, and third vapor deposition sources 12, 13, and 35 are operated at the same time, and by appropriately operating the first, second, and third switching valves 16, 22, and 37, vapor deposition particles of the host material 14h, vapor deposition particles of the dopant material 14d, and vapor deposition particles of the assist material 14a from the first and second vapor deposition sources 12, 13, and 35 are successively allowed to flow one at a time into the common pipe 42 via the corresponding one of the first, second, and third switching valves 16, 22, and 37. Also, in the vapor deposition device 11 of the present embodiment, vapor deposition particles of the host material 14h, vapor deposition particles of the dopant material 14d, and vapor deposition particles of the assist material 14a are successively fed from the common pipe 42 into the vapor deposition particle emission source 43, and then emitted from the vapor deposition particle emission source 43 as vapor deposition particles 44 bound for the substrate S.

Also, similarly to the vapor deposition device of the first embodiment, the vapor deposition device 11 of the present embodiment is a cluster type of device for vapor depositing the above-described vapor deposition particles on one substrate S inside the vacuum chamber 28, and, furthermore, the vapor deposition device 11 of the present embodiment constitutes a scanning vapor deposition device in which a mask (not shown) for forming the light emitting layer 5 in a predetermined pattern is provided between the vapor deposition particle emission source 43 and the substrate S, and in which the substrate S and the mask move along directions perpendicular to the paper surface of FIG. 5 when the vapor deposition particles are emitted from the vapor deposition particle emission source 43. Accordingly, the light emitting layer 5, which is a film in a predetermined pattern, is formed on the substrate S.

Also, the vapor deposition device 11 of the present embodiment is configured such that when the emission of vapor deposition particles of the host material 14h, vapor deposition particles of the dopant material 14d, or vapor deposition particles of the assist material 14a onto the substrate S has ended, the exhaust pump 34 evacuates the vapor deposition particles.

Specifically, when the emission of vapor deposition particles of the host material 14h has ended, the exhaust pump 34 evacuates vapor deposition particles of the host material 14h that exist inside the pipe 17 (including the pipe 17 side of the inside of the first switching valve 16 as well), inside the pipe 23 (including the pipe 23 side of the inside of the second switching valve 22 as well), inside the pipe 38 (including the pipe 38 side of the inside of the third switching valve 37 as well), inside the common pipe 42, and inside the vapor deposition particle emission source 43, to the outside via the pipe 31, the exhaust valve 32, and the pipe 33.

Also, when the emission of vapor deposition particles of the dopant material 14d has ended, the exhaust pump 34 evacuates vapor deposition particles of the dopant material 14d that exist inside the pipe 17 (including the pipe 17 side of the inside of the first switching valve 16 as well), inside the pipe 23 (including the pipe 23 side of the inside of the second switching valve 22 as well), inside the pipe 38 (including the pipe 38 side of the inside of the third switching valve 37 as well), inside the common pipe 42, and inside the vapor deposition particle emission source 43, to the outside via the pipe 31, the exhaust valve 32, and the pipe 33.

Also, when the emission of vapor deposition particles of the assist material 14a has ended, the exhaust pump 34 evacuates vapor deposition particles of the assist material 14a that exist inside the pipe 17 (including the pipe 17 side of the inside of the first switching valve 16 as well), inside the pipe 23 (including the pipe 23 side of the inside of the second switching valve 22 as well), inside the pipe 38 (including the pipe 38 side of the inside of the third switching valve 37 as well), inside the common pipe 42, and inside the vapor deposition particle emission source 43, to the outside via the pipe 31, the exhaust valve 32, and the pipe 33.

Also, in the vapor deposition device 11 of the present embodiment, the first, second, and third vapor deposition sources 12, 13, and 35 are operated at the same time and respectively produce vapor deposition particles of the host material 14h, vapor deposition particles of the dopant material 14d, and vapor deposition particles of the assist material 14a, and therefore when vapor deposition particles of the host material 14h are allowed to flow into the common pipe 42, the second exhaust valve 26 evacuates the vapor deposition particles of the dopant material 14d from the second vapor deposition source 13 to the outside via the pipe 25, and the third exhaust valve 41 evacuates the vapor deposition particles of the assist material 14a from the third vapor deposition source 35 to the outside via the pipe 40.

Also, when vapor deposition particles of the dopant material 14d are allowed to flow into the common pipe 42, the first exhaust valve 20 evacuates the vapor deposition particles of the host material 14h from the first vapor deposition source 12 to the outside via the pipe 19, and the third exhaust valve 41 evacuates the vapor deposition particles of the assist material 14a from the third vapor deposition source 35 to the outside via the pipe 40.

Also, when vapor deposition particles of the assist material 14a are allowed to flow into the common pipe 42, the first exhaust valve 20 evacuates the vapor deposition particles of the host material 14h from the first vapor deposition source 12 to the outside via the pipe 19, and the second exhaust valve 26 evacuates the vapor deposition particles of the dopant material 14d from the second vapor deposition source 13 to the outside via the pipe 25.

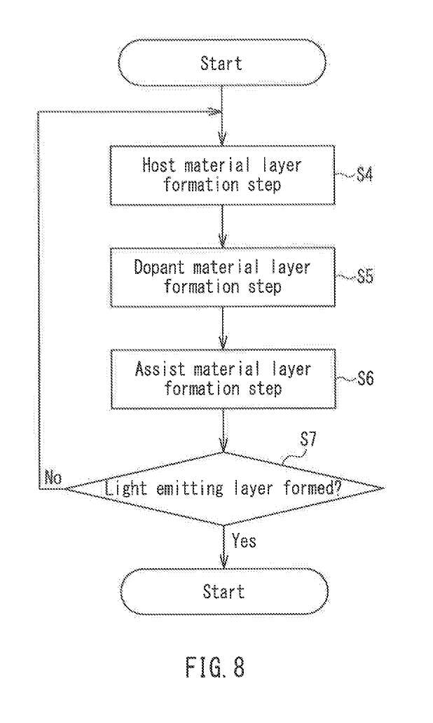

Next, a vapor deposition method performed by the vapor deposition device 11 of the present embodiment will be described in detail with reference to FIGS. 8 to 11 as well.

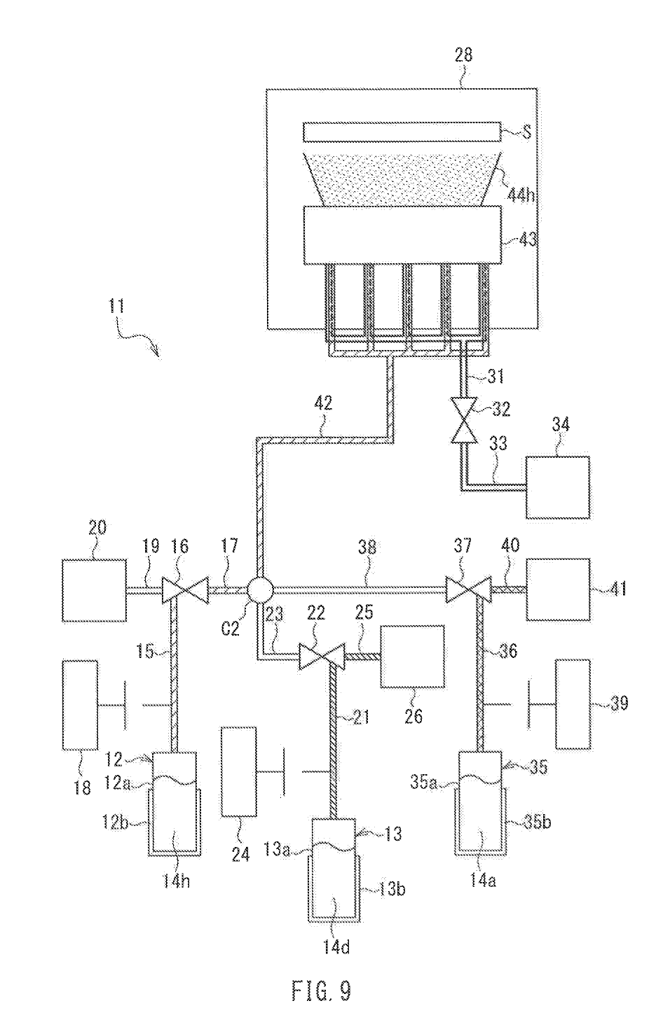

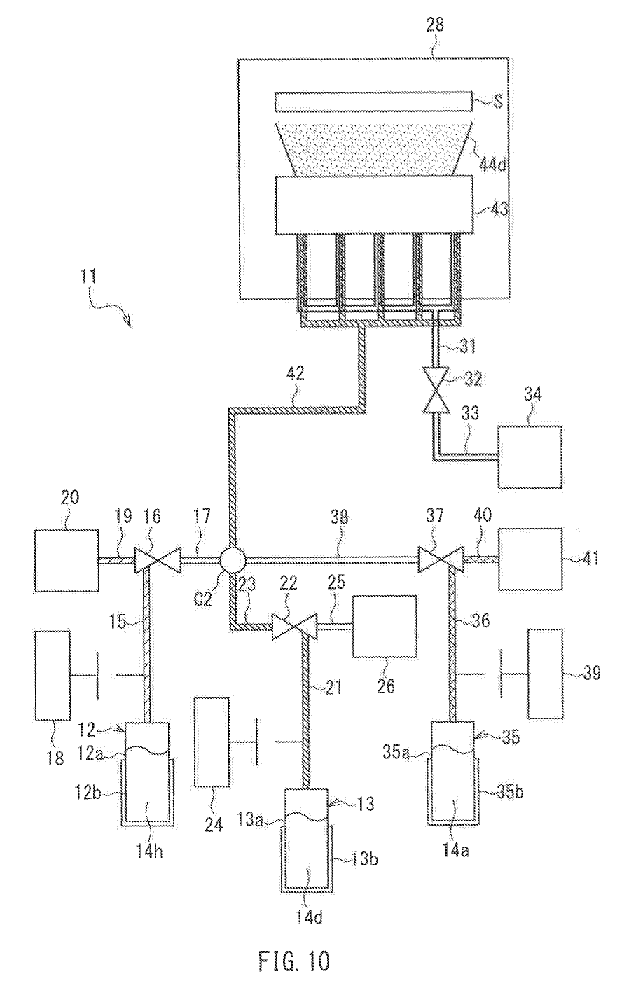

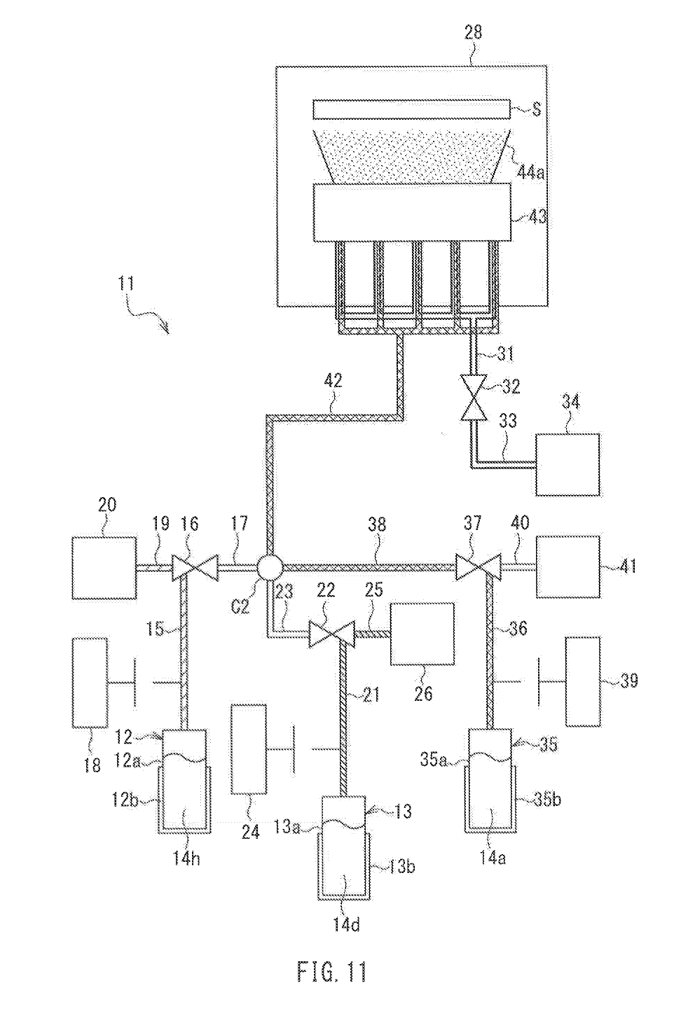

FIG. 8 is a flowchart illustrating the vapor deposition method according to the second embodiment of the present invention. FIG. 9 is a diagram illustrating an operation state of the vapor deposition device shown in FIG. 7 in a host material layer formation step shown in FIG. 8. FIG. 10 is a diagram illustrating an operation state of the vapor deposition device shown in FIG. 7 in a dopant material layer material formation step shown in FIG. 8. FIG. 11 is a diagram illustrating an operation state of the vapor deposition device shown in FIG. 7 in an assist material layer material formation step shown in FIG. 8.

As shown in step S4 in FIG. 8, in the present embodiment, first, a host material layer formation step of forming the host material layer 5a on the substrate S is performed.

Specifically, this host material layer formation step is divided into a mid-vapor deposition step of vapor depositing vapor deposition particles of the host material 14h and a post-vapor deposition step performed thereafter.

In the mid-vapor deposition step of vapor depositing vapor deposition particles of the host material 14h, the first, second, and third vapor deposition sources 12, 13, and 35 are operated at the same time, and vapor deposition particles of the host material 14h, vapor deposition particles of the dopant material 14d, and vapor deposition particles of the assist material 14a are produced.

Also, the junction point C1 side of the first switching valve 16 is opened, and the first switching valve 16 connects the first vapor deposition source 12 and the (one) common pipe 42. Also, the second exhaust pump 26 side of the second switching valve 22 is opened, and the second switching valve 22 connects the second vapor deposition source 13 and the second exhaust pump 26. Also, the third exhaust pump 41 side of the third switching valve 37 is opened, and the third switching valve 37 connects the third vapor deposition source 35 and the third exhaust pump 41. Also, the exhaust valve 32 is closed. Furthermore, the second and third exhaust pumps 26 and 41 operate.

Accordingly, in this mid-vapor deposition step, vapor deposition particles of the host material 14h pass through the pipe 15, the pipe 17, the junction point C1, and the common pipe 42 as shown by the left-downward diagonal hatching in FIG. 9, and are emitted as vapor deposition particles 44h from the vapor deposition particle emission source 43. As a result, the host material layer 5a is formed on the substrate S. Meanwhile, vapor deposition particles of the dopant material 14d pass through the pipe 21 and the pipe 25 as shown by the right-downward diagonal hatching in FIG. 9, and are evacuated by the second exhaust pump 26. Also, vapor deposition particles of the assist material 14a pass through the pipe 36 and the pipe 40 and are evacuated by the third exhaust pump 41 as shown by the cross-hatching in FIG. 9. Note that in this mid-vapor deposition step, the first exhaust pump 20 and the exhaust pump 34 are put in the on (operating) state or off (stopped) state.

Next, in the post-vapor deposition step, the first, second, and third vapor deposition sources 12, 13, and 35 are operated at the same time. Also, the first exhaust pump 20 side of the first switching valve 16 is opened, and the first switching valve 16 connects the first vapor deposition source 12 and the first exhaust pump 20. Also, the second exhaust pump 26 side of the second switching valve 22 is opened, and the second switching valve 22 connects the second vapor deposition source 13 and the second exhaust pump 26. Also, the third exhaust pump 41 side of the third switching valve 37 is opened, and the third switching valve 37 connects the third vapor deposition source 35 and the third exhaust pump 41. Also, the exhaust valve 32 is opened. Furthermore, the first, second, and third exhaust pumps 20, 26, and 41 and the exhaust pump 34 operate.

Accordingly, in this post-vapor deposition step, the first exhaust pump 20 evacuates vapor deposition particles of the host material 14h that exist inside the pipe 15 and inside the pipe 19 (including the pipe 19 side of the inside of the first switching valve 16 as well). In other words, vapor deposition particles of the host material 14h from the first vapor deposition source 12 are evacuated by the first exhaust pump 20.

Also, the second exhaust pump 26 evacuates vapor deposition particles of the dopant material 14d that exist inside the pipe 21 and inside the pipe 25 (including the pipe 25 side of the inside of the second switching valve 22 as well). In other words, vapor deposition particles of the dopant material 14d from the second vapor deposition source 13 are evacuated by the second exhaust pump 26.

Also, the third exhaust pump 41 evacuates vapor deposition particles of the assist material 14a that exist inside the pipe 36 and inside the pipe 40 (including the pipe 40 side of the inside of the third switching valve 37 as well). In other words, vapor deposition particles of the assist material 14a from the third vapor deposition source 35 are evacuated by the third exhaust pump 41.

Furthermore, the exhaust pump 34 evacuates vapor deposition particles of the host material 14h that exist inside the pipe 17 (including the pipe 17 side of the first switching valve 16 as well), inside the pipe 23 (including the pipe 23 side of the inside of the second switching valve 22 as well), inside the pipe 38 (including the pipe 38 side of the inside of the third switching valve 37 as well), inside the common pipe 42, and inside the vapor deposition particle emission source 43.

Next, as shown in step S5 in FIG. 8, a dopant material layer formation step of forming the dopant material layer 5b is performed.

Specifically, this dopant material layer formation step is divided into a mid-vapor deposition step of vapor depositing vapor deposition particles of the dopant material 14d and a post-vapor deposition step performed thereafter.

In the mid-vapor deposition step of vapor depositing vapor deposition particles of the dopant material 14d, the first, second, and third vapor deposition sources 12, 13, and 35 are operated at the same time, and vapor deposition particles of the host material 14h, vapor deposition particles of the dopant material 14d, and vapor deposition particles of the assist material 14a are produced.

Also, the first exhaust pump 20 side of the first switching valve 16 is opened, and the first switching valve 16 connects the first vapor deposition source 12 and the first exhaust pump 20. Also, the junction point C1 side of the second switching valve 22 is opened, and the second switching valve 22 connects the second vapor deposition source 13 and the (one) common pipe 42. Also, the third exhaust pump 41 side of the third switching valve 37 is opened, and the third switching valve 37 connects the third vapor deposition source 35 and the third exhaust pump 41. Also, the exhaust valve 32 is closed. Furthermore, the first and third exhaust pumps 20 and 41 operate.

Accordingly, in this mid-vapor deposition step, vapor deposition particles of the dopant material 14d pass through the pipe 21, the pipe 23, the junction point C1, and the common pipe 42 as shown by the right-downward diagonal hatching in FIG. 10, and are emitted as vapor deposition particles 44d from the vapor deposition particle emission source 43. As a result, the dopant material layer 5b is formed on the substrate S. Meanwhile, vapor deposition particles of the host material 14h pass through the pipe 15 and the pipe 19 as shown by the left-downward diagonal hatching in FIG. 10, and are evacuated by the first exhaust pump 20. Also, vapor deposition particles of the assist material 14a pass through the pipe 36 and the pipe 40 and are evacuated by the third exhaust pump 41 as shown by the cross-hatching in FIG. 10. Note that in this mid-vapor deposition step, the second exhaust pump 26 and the exhaust pump 34 are put in the on (operating) state or off (stopped) state.

Next, in the post-vapor deposition step, the first, second, and third vapor deposition sources 12, 13, and 35 are operated at the same time. Also, the first exhaust pump 20 side of the first switching valve 16 is opened, and the first switching valve 16 connects the first vapor deposition source 12 and the first exhaust pump 20. Also, the second exhaust pump 26 side of the second switching valve 22 is opened, and the second switching valve 22 connects the second vapor deposition source 13 and the second exhaust pump 26. Also, the third exhaust pump 41 side of the third switching valve 37 is opened, and the third switching valve 37 connects the third vapor deposition source 35 and the third exhaust pump 41. Also, the exhaust valve 32 is opened. Furthermore, the first, second, and third exhaust pumps 20, 26, and 41 and the exhaust pump 34 operate.

Accordingly, in this post-vapor deposition step, the first exhaust pump 20 evacuates vapor deposition particles of the host material 14h that exist inside the pipe 15 and inside the pipe 19 (including the pipe 19 side of the inside of the first switching valve 16 as well). In other words, vapor deposition particles of the host material 14h from the first vapor deposition source 12 are evacuated by the first exhaust pump 20.

Also, the second exhaust pump 26 evacuates vapor deposition particles of the dopant material 14d that exist inside the pipe 21 and inside the pipe 25 (including the pipe 25 side of the inside of the second switching valve 22). In other words, vapor deposition particles of the dopant material 14d from the second vapor deposition source 13 are evacuated by the second exhaust pump 26.

Also, the third exhaust pump 41 evacuates vapor deposition particles of the assist material 14a that exist inside the pipe 36 and inside the pipe 40 (including the pipe 40 side of the inside of the third switching valve 37 as well). In other words, vapor deposition particles of the assist material 14a from the third vapor deposition source 35 are evacuated by the third exhaust pump 41.

Furthermore, the exhaust pump 34 evacuates vapor deposition particles of the dopant material 14d that exist inside the pipe 17 (including the pipe 17 side of the first switching valve 16 as well), inside the pipe 23 (including the pipe 23 side of the inside of the second switching valve 22 as well), inside the pipe 38 (including the pipe 38 side of the inside of the third switching valve 37 as well), inside the common pipe 42, and inside the vapor deposition particle emission source 43.

Next, as shown in step S6 in FIG. 8, an assist material layer formation step of forming the assist material layer 5c is performed.

Specifically, this assist material layer formation step is divided into a mid-vapor deposition step of vapor depositing vapor deposition particles of the assist material 14a and a post-vapor deposition step performed thereafter.

In the mid-vapor deposition step of vapor depositing vapor deposition particles of the assist material 14a, the first, second, and third vapor deposition sources 12, 13, and 35 are operated at the same time, and vapor deposition particles of the host material 14h, vapor deposition particles of the dopant material 14d, and vapor deposition particles of the assist material 14a are produced.

Also, the first exhaust pump 20 side of the first switching valve 16 is opened, and the first switching valve 16 connects the first vapor deposition source 12 and the first exhaust pump 20. Also, the second exhaust pump 26 side of the second switching valve 22 is opened, and the second switching valve 22 connects the second vapor deposition source 13 and the second exhaust pump 26. Also, the junction point C1 side of the third switching valve 37 is opened, and the third switching valve 37 connects the third vapor deposition source 35 and the (one) common pipe 42. Also, the exhaust valve 32 is closed. Furthermore, the first and third exhaust pumps 20 and 41 operate.

Accordingly, in this mid-vapor deposition step, vapor deposition particles of the assist material 14a pass through the pipe 36, the pipe 38, the junction point C1, and the common pipe 42, and are emitted as vapor deposition particles 44a from the vapor deposition particle emission source 43 as shown by the cross-hatching in FIG. 11. As a result, the assist material layer 5c is formed on the substrate S. Meanwhile, vapor deposition particles of the host material 14h pass through the pipe 15 and the pipe 19 as shown by the left-downward diagonal hatching in FIG. 11, and are evacuated by the first exhaust pump 20. Also, vapor deposition particles of the dopant material 14d pass through the pipe 21 and the pipe 25 as shown by the right-downward diagonal hatching in FIG. 11, and are evacuated by the second exhaust pump 26. Note that in this mid-vapor deposition step, the third exhaust pump 41 and the exhaust pump 34 are put in the on (operating) state or off (stopped) state.

Next, in the post-vapor deposition step, the first, second, and third vapor deposition sources 12, 13, and 35 are operated at the same time. Also, the first exhaust pump 20 side of the first switching valve 16 is opened, and the first switching valve 16 connects the first vapor deposition source 12 and the first exhaust pump 20. Also, the second exhaust pump 26 side of the second switching valve 22 is opened, and the second switching valve 22 connects the second vapor deposition source 13 and the second exhaust pump 26. Also, the third exhaust pump 41 side of the third switching valve 37 is opened, and the third switching valve 37 connects the third vapor deposition source 35 and the third exhaust pump 41. Also, the exhaust valve 32 is opened. Furthermore, the first, second, and third exhaust pumps 20, 26, and 41 and the exhaust pump 34 operate.

Accordingly, in this post-vapor deposition step, the first exhaust pump 20 evacuates vapor deposition particles of the host material 14h that exist inside the pipe 15 and inside the pipe 19 (including the pipe 19 side of the inside of the first switching valve 16 as well). In other words, vapor deposition particles of the host material 14h from the first vapor deposition source 12 are evacuated by the first exhaust pump 20.

Also, the second exhaust pump 26 evacuates vapor deposition particles of the dopant material 14d that exist inside the pipe 21 and inside the pipe 25 (including the pipe 25 side of the inside of the second switching valve 22 as well). In other words, vapor deposition particles of the dopant material 14d from the second vapor deposition source 13 are evacuated by the second exhaust pump 26.

Also, the third exhaust pump 41 evacuates vapor deposition particles of the assist material 14a that exist inside the pipe 36 and inside the pipe 40 (including the pipe 40 side of the inside of the third switching valve 37 as well). In other words, vapor deposition particles of the assist material 14a from the third vapor deposition source 35 are evacuated by the third exhaust pump 41.

Furthermore, the exhaust pump 34 evacuates vapor deposition particles of the assist material 14a that exist inside the pipe 17 (including the pipe 17 side of the first switching valve 16 as well), inside the pipe 23 (including the pipe 23 side of the inside of the second switching valve 22 as well), inside the pipe 38 (including the pipe 38 side of the inside of the third switching valve 37 as well), inside the common pipe 42, and inside the vapor deposition particle emission source 43.

Next, as shown in step S7 in FIG. 6, it is determined whether or not the light emitting layer 5 was formed. In other words, it is determined whether the light emitting layer 5 was formed to a predetermined thickness (e.g., 300 Å), and the vapor deposition step is ended if it is determined that the light emitting layer 5 has been formed to the predetermined thickness. On the other hand, the procedure returns to step S4 if it is determined that the light emitting layer 5 has not been formed to the predetermined thickness.

Note that in the host material layer formation step, the host material 14h is vapor deposited at a rate of 3 Å/s for example. Also, in the dopant material layer formation step, the dopant material 14d is vapor deposited at a rate of 0.3 Å/s for example. Also, in the assist material layer formation step, the assist material 14a is vapor deposited at a rate of 1 Å/s for example. Also, the switching intervals of the first, second, and third switching valves 16, 22, and 37 are 1 time per second for example.

According to the above configuration, actions and effects similar to those of the first embodiment can be achieved in the present embodiment. Also, in the present embodiment, the third vapor deposition source 35 for producing vapor deposition particles of the assist material 14a is provided in addition to the first and second vapor deposition sources 12 and 13, and vapor deposition particles of the host material 14h, vapor deposition particles of the dopant material 14d, and vapor deposition particles of the assist material 14a, are successively emitted from the one vapor deposition particle emission source 43. Accordingly, in the present embodiment, the host material layer 5a, the dopant material layer 5b, and the assist material layer 5c can be formed precisely, and the light emitting layer (co-deposition film) 5 made up of the host material layer 5a, the dopant material layer 5b, and the assist material layer 5c can also be formed precisely.

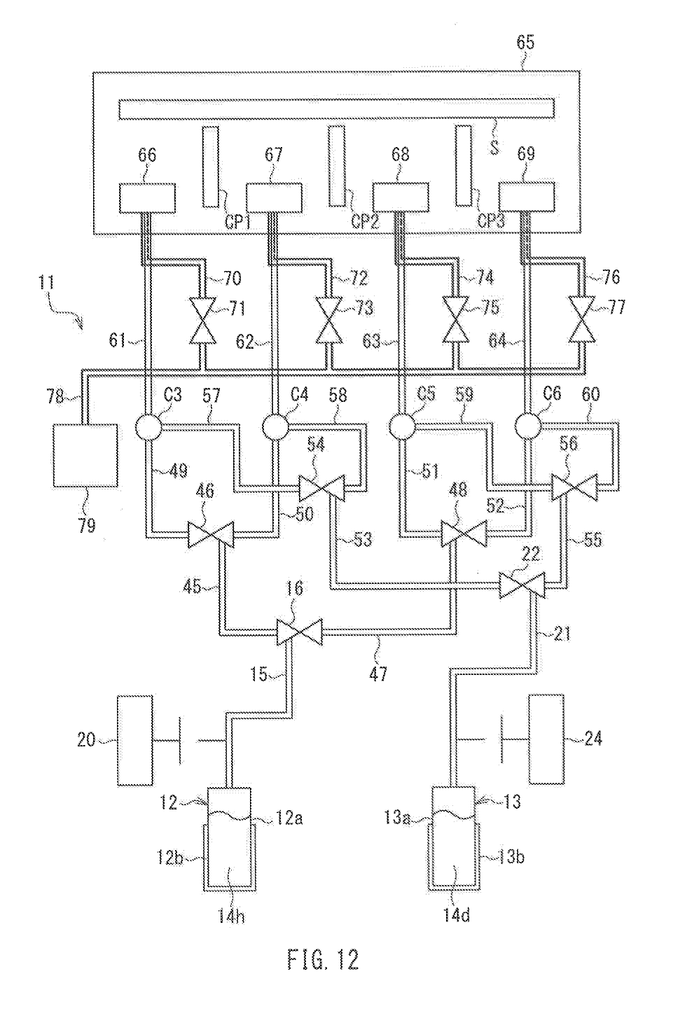

FIG. 12 is a diagram illustrating a vapor deposition device according to a third embodiment of the present invention.

A main difference between the present embodiment and the first embodiment in this figure is that vapor deposition particles of the host material from the first vapor deposition source and vapor deposition particles of the dopant material from the second vapor deposition source are emitted from separate vapor deposition particle emission sources so as to not be overlapped on the substrate, in order to form a light emitting layer that is a laminate structure made up of the host material layer and the dopant material layer. Note that elements that are in common with the first embodiment are denoted by the same reference signs, and redundant descriptions will not be given for them.

Specifically, as shown in FIG. 12, in the vapor deposition device 11 of the present embodiment, the first switching valve 16 is connected to a third switching valve 46 via a pipe 45, and is also connected to a fourth switching valve 48 via a pipe 47. Furthermore, this first switching valve 16 is configured to appropriately switch between putting the pipe 15 and the pipe 45 into communication and putting the pipe 15 and the pipe 47 into communication.

Also, the third switching valve 46 is connected to a junction point C3, which is one end portion of a first common pipe 61 as the at least one common pipe, via a pipe 49, and the third switching valve 46 is also connected to a junction point C4, which is one end portion of a second common pipe 62 as the at least one common pipe, via a pipe 50. Furthermore, the third switching valve 46 is configured to appropriately switch between putting the pipe 45 and the pipe 49 into communication and putting the pipe 45 and the pipe 50 into communication.

Also, the fourth switching valve 48 is connected to a junction point C5, which is one end portion of a third common pipe 63 as the at least one common pipe, via a pipe 51, and the fourth switching valve 48 is also connected to a junction point C6, which is one end portion of a fourth common pipe 64 as the at least one common pipe, via a pipe 52. Furthermore, the fourth switching valve 48 is configured to appropriately switch between putting the pipe 47 and the pipe 51 into communication and putting the pipe 47 and the pipe 52 into communication.

Also, the second switching valve 22 is connected to a fifth switching valve 54 via a pipe 53, and is connected to a sixth switching valve 56 via a pipe 55. Furthermore, this second switching valve 22 is configured to appropriately switch between putting the pipe 21 and the pipe 53 into communication and putting the pipe 21 and the pipe 55 into communication.

Also, the fifth switching valve 54 is connected to the junction point C3 via a pipe 57, and the fifth switching valve 54 is connected to the junction point C4 via a pipe 58. Furthermore, the fifth switching valve 54 is configured to appropriately switch between putting the pipe 53 and the pipe 57 into communication and putting the pipe 53 and the pipe 58 into communication.

Also, the sixth switching valve 56 is connected to the junction point C5 via a pipe 59, and the sixth switching valve 56 is connected to the junction point C6 via a pipe 60. Furthermore, the sixth switching valve 56 is configured to appropriately switch between putting the pipe 55 and the pipe 59 into communication and putting the pipe 55 and the pipe 60 into communication.

Also, the first, second, third, and fourth common pipes 61, 62, 63, and 64 are respectively connected to first, second, third, and fourth vapor deposition particle emission sources 66, 67, 68, and 69 provided in a vacuum chamber 65. These first, second, third, and fourth vapor deposition particle emission sources 66, 67, 68, and 69 each have a hole portion (not shown) for emitting vapor deposition particles.

Also, a first exhaust valve 71 is connected to the first vapor deposition particle emission source 66 via a pipe 70, and a second exhaust valve 73 is connected to the second vapor deposition particle emission source 67 via a pipe 72. Also, a third exhaust valve 75 is connected to the third vapor deposition particle emission source 68 via a pipe 74, and a fourth exhaust valve 77 is connected to the fourth vapor deposition particle emission source 69 via a pipe 76.

Also, one exhaust pump 79 is connected to the first, second, third, and fourth exhaust valves 71, 73, 75, and 77 via a pipe 78.

Also, in the vapor deposition device 11 of the present embodiment, control plates CP1, CP2, and CP3 are formed between the substrate S and adjacent pairs of vapor deposition particle emission sources among the first to fourth vapor deposition particle emission sources 66 to 69. Specifically, as shown in FIG. 12, the control plate CP1 is formed between the substrate S and the first and second vapor deposition particle emission sources 66 and 67, prevents vapor deposition particles from the first vapor deposition particle emission source 66 from being emitted onto a region of the substrate S that opposes the second vapor deposition particle emission source 67, and prevents vapor deposition particles from the second vapor deposition particle emission source 67 from being emitted on a region of the substrate S that opposes the first vapor deposition particle emission source 66.

Also, the control plate CP2 is formed between the substrate S and the second and third vapor deposition particle emission sources 67 and 68, prevents vapor deposition particles from the second vapor deposition particle emission source 67 from being emitted onto a region of the substrate S that opposes the third vapor deposition particle emission source 68, and prevents vapor deposition particles from the third vapor deposition particle emission source 68 from being emitted on a region of the substrate S that opposes the second vapor deposition particle emission source 67.

Also, the control plate CP3 is formed between the substrate S and the third and fourth vapor deposition particle emission sources 68 and 69, prevents vapor deposition particles from the third vapor deposition particle emission source 68 from being emitted onto a region of the substrate S that opposes the fourth vapor deposition particle emission source 69, and prevents vapor deposition particles from the fourth vapor deposition particle emission source 69 from being emitted on a region of the substrate S that opposes the third vapor deposition particle emission source 68.

Also, in the vapor deposition device 11 of the present embodiment, the first and second vapor deposition sources 12 and 13 are operated at the same time, and by appropriately operating the first, second, third, fourth, fifth, and sixth switching valves 16, 22, 46, 48, 54, and 56, vapor deposition particles of the host material 14h from the first vapor deposition source 12 are emitted from any one vapor deposition particle emission source among the first to fourth vapor deposition particle emission sources 66 to 69, and vapor deposition particles of the dopant material 14d from the second vapor deposition source 13 are emitted from any one vapor deposition particle emission source among the first to fourth vapor deposition particle emission sources 66 to 69 that is different from the vapor deposition particle emission source that emits vapor deposition particles of the host material 14h.

Also, similarly to the vapor deposition device of the first embodiment, the vapor deposition device 11 of the present embodiment is a cluster type of device for vapor depositing the above-described vapor deposition particles on one substrate S inside the vacuum chamber 65. Also, in the vapor deposition device 11 of the present embodiment, vapor deposition particles of the host material 14h and vapor deposition particles of the dopant material 14d are emitted so as to not be overlapped on the substrate S. Furthermore, the vapor deposition device 11 of the present embodiment constitutes a scanning vapor deposition device in which a mask (not shown) for forming the light emitting layer 5 in a predetermined pattern is provided between the substrate S and the first to fourth vapor deposition particle emission sources 66 to 69, and in which the substrate S and the mask move along the left-right direction in FIG. 12 when the vapor deposition particles are emitted. Accordingly, similarly to the vapor deposition device of the first embodiment, the light emitting layer 5 that is a laminate structure made up of the host material layer 5a and the dopant material layer 5b is formed as a film on the substrate S.

Also, in the vapor deposition device 11 of the present embodiment, the exhaust pump 79 evacuates vapor deposition particles from the inside of among the first to fourth vapor deposition particle emission sources 66 to 69, the two vapor deposition particle emission sources that are not emitting vapor deposition particles of the host material 14h or the dopant material 14d, and the inside of the pipes and the exhaust valves that are connected to those two vapor deposition particle emission sources.

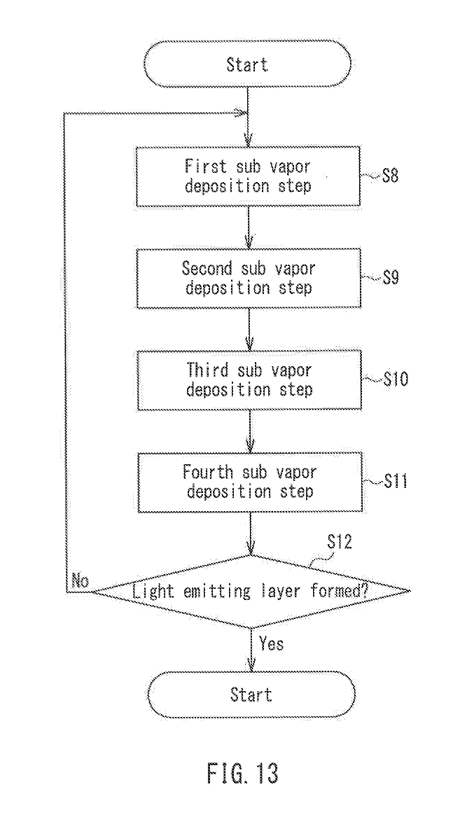

Next, a vapor deposition method performed by the vapor deposition device 11 of the present embodiment will be described in detail with reference to FIGS. 13 to 17 as well.

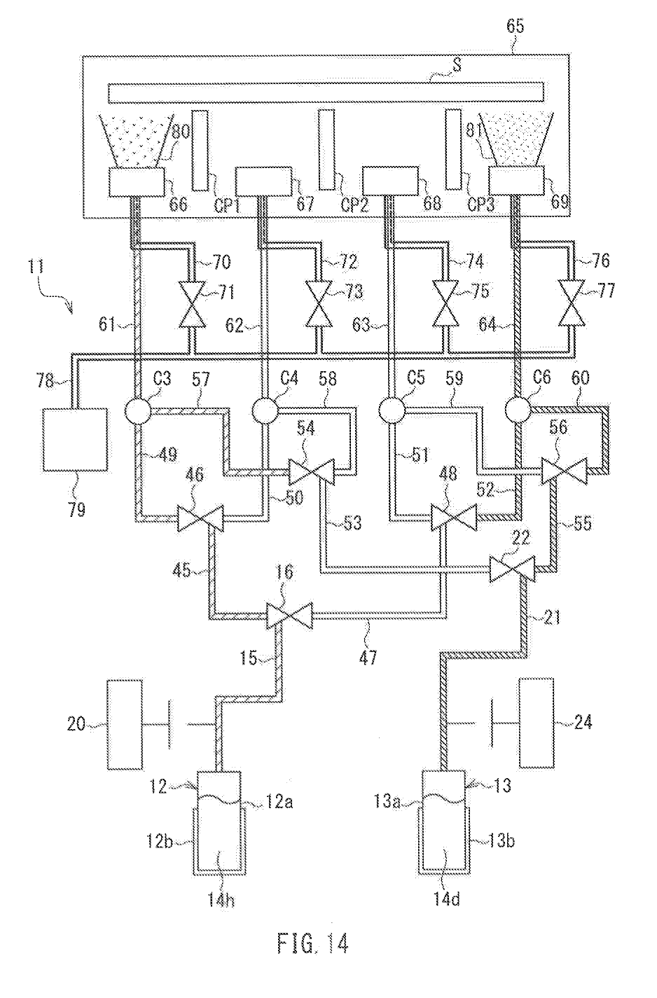

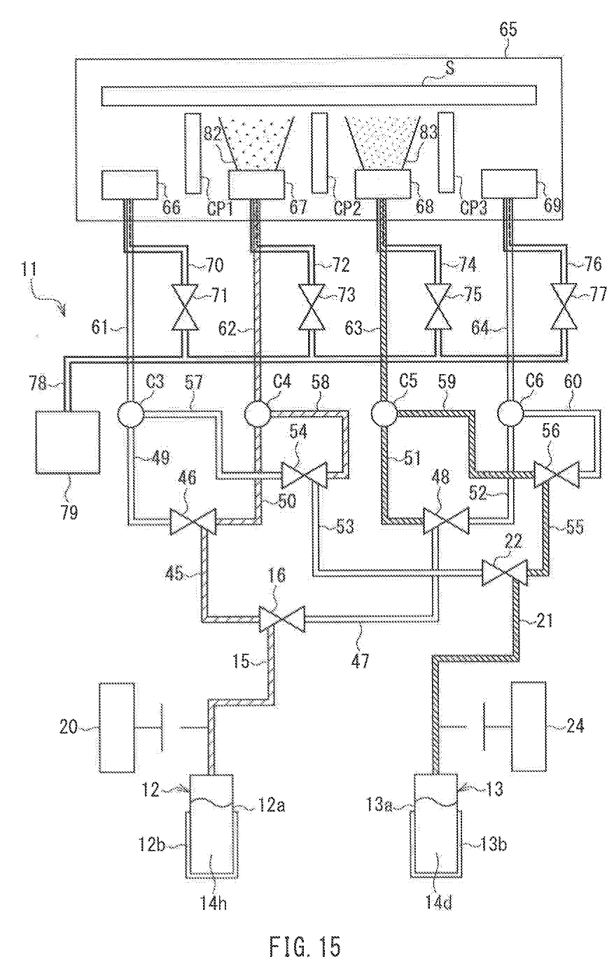

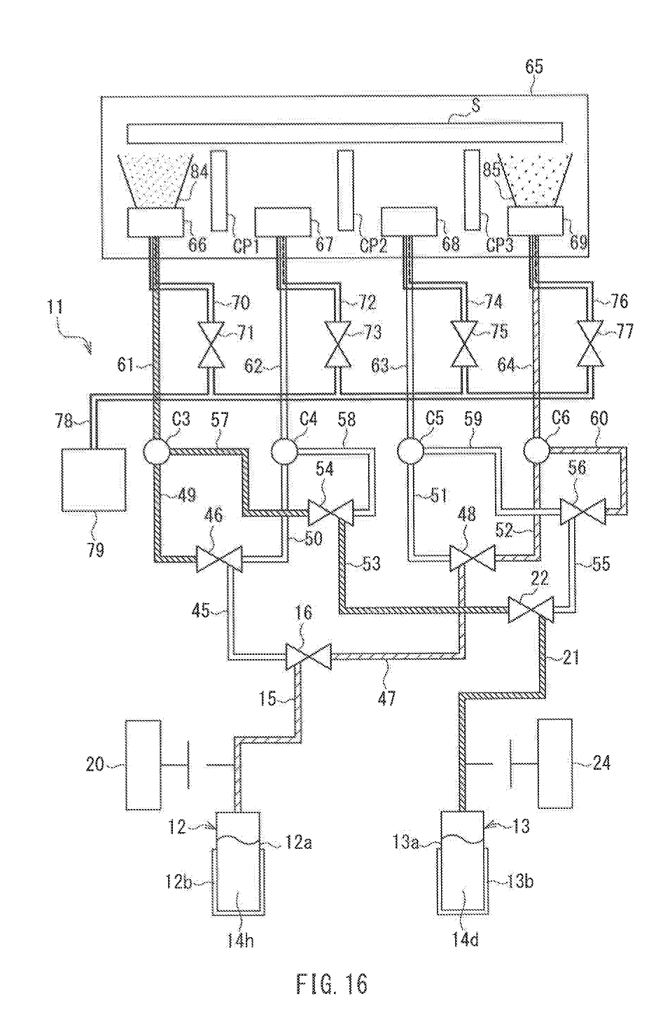

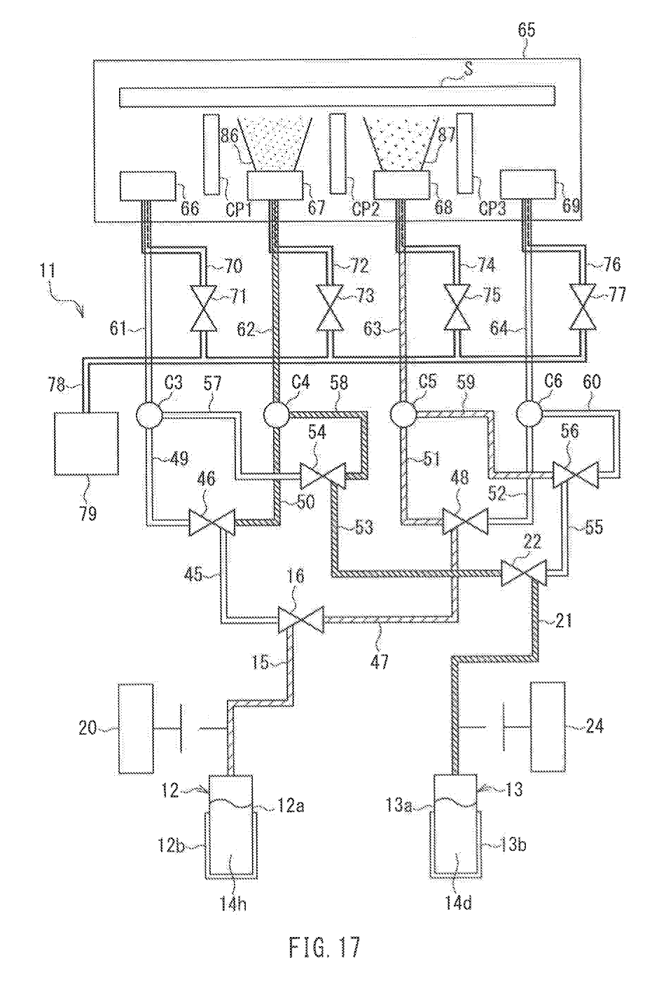

FIG. 13 is a flowchart illustrating a vapor deposition method according to the third embodiment of the present invention. FIG. 14 is a diagram illustrating an operation state of the vapor deposition device shown in FIG. 12 in a first sub vapor deposition step shown in FIG. 13. FIG. 15 is a diagram illustrating an operation state of the vapor deposition device shown in FIG. 12 in a second sub vapor deposition step shown in FIG. 13. FIG. 16 is a diagram illustrating an operation state of the vapor deposition device shown in FIG. 12 in a third sub vapor deposition step shown in FIG. 13. FIG. 17 is a diagram illustrating an operation state of the vapor deposition device shown in FIG. 12 in a fourth sub vapor deposition step shown in FIG. 13.

As shown in FIG. 13, in the vapor deposition device 11 of the present embodiment, the vapor deposition step includes first to fourth sub vapor deposition steps. Also, as shown in step S8 in FIG. 13, in the present embodiment, first, a first sub vapor deposition step is performed in which vapor deposition particles of the host material 14h from the first vapor deposition source 12 are emitted from the first vapor deposition particle emission source 66 onto the substrate S, and vapor deposition particles of the dopant material 14d from the second vapor deposition source 13 are emitted from the fourth vapor deposition particle emission source 69 onto the substrate S.

Specifically, in FIG. 14, in the first sub vapor deposition step, the third switching valve 46 side of the first switching valve 16 is opened, and the sixth switching valve 56 side of the second switching valve 22 is opened. Also, the junction point C3 side of the third switching valve 46 is opened, and the junction point C5 side of the fourth switching valve 48 is opened. Also, the junction point C4 side of the fifth switching valve 54 is opened, and the junction point C6 side of the sixth switching valve 56 is opened. Also, the first and fourth exhaust valves 71 and 77 are closed.

Also, in the first sub vapor deposition step, vapor deposition particles of the host material 14h from the first vapor deposition source 12 flow inside the pipes 15, 45, 49, 57, and 61 as shown by left-downward diagonal hatching in FIG. 14, and are emitted from the first vapor deposition particle emission source 66 onto the substrate S as vapor deposition particles 80. At the same time, vapor deposition particles of the dopant material 14d from the second vapor deposition source 13 flow inside the pipes 21, 55, 60, 52, and 64 as shown by right-downward diagonal hatching in FIG. 14, and are emitted from the fourth vapor deposition particle emission source 69 onto the substrate S as vapor deposition particles 81. Also, the vapor deposition particles of the host material 14h and the vapor deposition particles of the dopant material 14d are emitted onto different regions of the substrate S so as to not be overlapped with each other.

Also, in the first sub vapor deposition step, the second and third exhaust valves 73 and 75 are open, and the exhaust pump 79 evacuates, to the outside, vapor deposition particles that are inside the second and third vapor deposition particle emission sources 67 and 68, inside the second and third exhaust valves 73 and 75, inside the pipes 72, 74, and 78, inside the pipes 62, 50, 58, 53, 63, 51, 59, and 47, inside the junction points C4 and C5, inside the pipe 47 side of the first switching valve 16, inside the pipe 53 side of the second switching valve 22, inside the pipe 50 side of the third switching valve 46, inside the pipe 51 side of the fourth switching valve 48, inside the pipe 58 side of the fifth switching valve 54, and inside the pipe 59 side of the sixth switching valve 56.

Next, as shown in step S9 in FIG. 13, in the present embodiment, a second sub vapor deposition step is performed in which vapor deposition particles of the host material 14h from the first vapor deposition source 12 are emitted from the second vapor deposition particle emission source 67 onto the substrate S, and vapor deposition particles of the dopant material 14d from the second vapor deposition source 13 are emitted from the third vapor deposition particle emission source 68 onto the substrate S.

Specifically, in FIG. 15, in the second sub vapor deposition step, the third switching valve 46 side of the first switching valve 16 is opened, and the sixth switching valve 56 side of the second switching valve 22 is opened. Also, the junction point C4 side of the third switching valve 46 is opened, and the junction point C6 side of the fourth switching valve 48 is opened. Also, the junction point C3 side of the fifth switching valve 54 is opened, and the junction point C5 side of the sixth switching valve 56 is opened. Also, the second and third exhaust valves 73 and 75 are closed.

Also, in the second sub vapor deposition step, vapor deposition particles of the host material 14h from the first vapor deposition source 12 flow inside the pipes 15, 45, 50, 58, and 62 as shown by left-downward diagonal hatching in FIG. 15, and are emitted from the second vapor deposition particle emission source 67 onto the substrate S as vapor deposition particles 82. At the same time, vapor deposition particles of the dopant material 14d from the second vapor deposition source 13 flow inside the pipes 21, 55, 59, 51, and 63 as shown by right-downward diagonal hatching in FIG. 15, and are emitted from the third vapor deposition particle emission source 68 onto the substrate S as vapor deposition particles 83. Also, the vapor deposition particles of the host material 14h and the vapor deposition particles of the dopant material 14d are emitted onto different regions of the substrate S so as to not be overlapped with each other.

Also, up to the point in time immediately before the second sub vapor deposition step (i.e., during the first sub vapor deposition step), the inside of the second and third vapor deposition particle emission sources 67 and 68 and the inside of the pipes 50, 51, 58, 59, 62, and 63 have been evacuated by the exhaust pump 79, and therefore corresponding vapor deposition particles can be vapor deposited in the second sub vapor deposition step while preventing contaminants and different materials from becoming mixed in.

Also, in the second sub vapor deposition step, the first and fourth exhaust valves 71 and 77 are open, and the exhaust pump 79 evacuates, to the outside, vapor deposition particles that are inside the first and fourth vapor deposition particle emission sources 66 and 69, inside the first and fourth exhaust valves 71 and 77, inside the pipes 70, 76, and 78, inside the pipes 61, 49, 57, 53, 64, 52, 60, and 47, inside the junction points C3 and C6, inside the pipe 47 side of the first switching valve 16, inside the pipe 53 side of the second switching valve 22, inside the pipe 49 side of the third switching valve 46, inside the pipe 52 side of the fourth switching valve 48, inside the pipe 57 side of the fifth switching valve 54, and inside the pipe 60 side of the sixth switching valve 56.

Next, as shown in step S10 in FIG. 13, in the present embodiment, a third sub vapor deposition step is performed in which vapor deposition particles of the host material 14h from the first vapor deposition source 12 are emitted from the fourth vapor deposition particle emission source 69 onto the substrate S, and vapor deposition particles of the dopant material 14d from the second vapor deposition source 13 are emitted from the first vapor deposition particle emission source 66 onto the substrate S.

Specifically, in FIG. 16, in the third sub vapor deposition step, the fourth switching valve 48 side of the first switching valve 16 is opened, and the fifth switching valve 54 side of the second switching valve 22 is opened. Also, the junction point C3 side of the third switching valve 46 is opened, and the junction point C6 side of the fourth switching valve 48 is opened. Also, the junction point C4 side of the fifth switching valve 54 is opened, and the junction point C5 side of the sixth switching valve 56 is opened. Also, the first and fourth exhaust valves 71 and 77 are closed.

Also, in the third sub vapor deposition step, vapor deposition particles of the host material 14h from the first vapor deposition source 12 flow inside the pipes 15, 47, 52, 60, and 64 as shown by left-downward diagonal hatching in FIG. 16, and are emitted from the fourth vapor deposition particle emission source 69 onto the substrate S as vapor deposition particles 85. At the same time, vapor deposition particles of the dopant material 14d from the second vapor deposition source 13 flow inside the pipes 21, 53, 57, 49, and 61 as shown by right-downward diagonal hatching in FIG. 16, and are emitted from the first vapor deposition particle emission source 66 onto the substrate S as vapor deposition particles 84. Also, the vapor deposition particles of the host material 14h and the vapor deposition particles of the dopant material 14d are emitted onto different regions of the substrate S so as to not be overlapped with each other.

Also, up to the point in time immediately before the third sub vapor deposition step (i.e., during the second sub vapor deposition step), the inside of the first and fourth vapor deposition particle emission sources 66 and 69 and the inside of the pipes 49, 52, 57, 60, 61, and 64 have been evacuated by the exhaust pump 79, and therefore corresponding vapor deposition particles can be vapor deposited in the third sub vapor deposition step while preventing contaminants and different materials from becoming mixed in.

Also, in the third sub vapor deposition step, the second and third exhaust valves 73 and 75 are open, and the exhaust pump 79 evacuates, to the outside, vapor deposition particles that are inside the second and third vapor deposition particle emission sources 67 and 68, inside the second and third exhaust valves 73 and 75, inside the pipes 72, 74, and 78, inside the pipes 62, 50, 58, 45, 63, 51, 59, and 55, inside the junction points C4 and C5, inside the pipe 45 side of the first switching valve 16, inside the pipe 55 side of the second switching valve 22, inside the pipe 50 side of the third switching valve 46, inside the pipe 51 side of the fourth switching valve 48, inside the pipe 58 side of the fifth switching valve 54, and inside the pipe 59 side of the sixth switching valve 56.

Next, as shown in step S11 in FIG. 13, in the present embodiment, a fourth sub vapor deposition step is performed in which vapor deposition particles of the host material 14h from the first vapor deposition source 12 are emitted from the third vapor deposition particle emission source 68 onto the substrate S, and vapor deposition particles of the dopant material 14d from the second vapor deposition source 13 are emitted from the second vapor deposition particle emission source 67 onto the substrate S.

Specifically, in FIG. 17, in the fourth sub vapor deposition step, the fourth switching valve 48 side of the first switching valve 16 is opened, and the fifth switching valve 54 side of the second switching valve 22 is opened. Also, the junction point C3 side of the third switching valve 46 is opened, and the junction point C5 side of the fourth switching valve 48 is opened. Also, the junction point C4 side of the fifth switching valve 54 is opened, and the junction point C6 side of the sixth switching valve 56 is opened. Also, the second and third exhaust valves 73 and 75 are closed.

Also, in the fourth sub vapor deposition step, vapor deposition particles of the host material 14h from the first vapor deposition source 12 flow inside the pipes 15, 47, 51, 59, and 63 as shown by left-downward diagonal hatching in FIG. 17, and are emitted from the third vapor deposition particle emission source 68 onto the substrate S as vapor deposition particles 87. At the same time, vapor deposition particles of the dopant material 14d from the second vapor deposition source 13 flow inside the pipes 21, 53, 58, 50, and 62 as shown by right-downward diagonal hatching in FIG. 17, and are emitted from the second vapor deposition particle emission source 67 onto the substrate S as vapor deposition particles 86. Also, the vapor deposition particles of the host material 14h and the vapor deposition particles of the dopant material 14d are emitted onto different regions of the substrate S so as to not be overlapped with each other.

Also, up to the point in time immediately before the fourth sub vapor deposition step (i.e., during the third sub vapor deposition step), the inside of the second and third vapor deposition particle emission sources 67 and 68 and the inside of the pipes 50, 51, 58, 59, 62, and 63 have been evacuated by the exhaust pump 79, and therefore corresponding vapor deposition particles can be vapor deposited in the fourth sub vapor deposition step while preventing contaminants and different materials from becoming mixed in.

Also, in the fourth sub vapor deposition step, the first and fourth exhaust valves 71 and 77 are open, and the exhaust pump 79 evacuates, to the outside, vapor deposition particles that are inside the first and fourth vapor deposition particle emission sources 66 and 69, inside the first and fourth exhaust valves 71 and 77, inside the pipes 70, 76, and 78, inside the pipes 61, 49, 57, 45, 64, 52, 60, and 55, inside the junction points C3 and C6, inside the pipe 45 side of the first switching valve 16, inside the pipe 55 side of the second switching valve 22, inside the pipe 49 side of the third switching valve 46, inside the pipe 52 side of the fourth switching valve 48, inside the pipe 57 side of the fifth switching valve 54, and inside the pipe 60 side of the sixth switching valve 56.

Next, as shown in step S12 in FIG. 13, it is determined whether or not the light emitting layer 5 was formed. In other words, it is determined whether the light emitting layer 5 was formed to a predetermined thickness (e.g., 300 Å), and the vapor deposition step is ended if it is determined that the light emitting layer 5 has been formed to the predetermined thickness. On the other hand, the procedure returns to step S8 if it is determined that the light emitting layer 5 has not been formed to the predetermined thickness.

Note that in the case of returning to step S8, that is to say in the case where the first sub vapor deposition step is performed subsequent to the fourth sub vapor deposition step, up to the point in time immediately before the first sub vapor deposition step (i.e., during the fourth sub vapor deposition step), the inside of the first and fourth vapor deposition particle emission sources 66 and 69 and the inside of the pipes 49, 52, 57, 60, 61, and 64 have been evacuated by the exhaust pump 79, and therefore corresponding vapor deposition particles can be vapor deposited in the first sub vapor deposition step while preventing contaminants and different materials from becoming mixed in.

According to the above configuration, actions and effects similar to those of the first embodiment can be achieved in the present embodiment. Also, in the present embodiment, by appropriately operating the first, second, third, fourth, fifth, and sixth switching valves 16, 22, 46, 48, 54, and 56, vapor deposition particles of the host material 14h from the first vapor deposition source 12 are emitted from any one vapor deposition particle emission source among the first to fourth vapor deposition particle emission sources 66 to 69, and vapor deposition particles of the dopant material 14d from the second vapor deposition source 13 are emitted from any one vapor deposition particle emission source among the first to fourth vapor deposition particle emission sources 66 to 69 that is different from the vapor deposition particle emission source that emits vapor deposition particles of the host material 14h. As a result, in the present embodiment, vapor deposition particles of the host material 14h and vapor deposition particles of the dopant material 14d can be emitted onto mutually different regions of the substrate S at the same time, thus making it possible to improve the utilization efficiency of vapor deposition particles of the host material 14h and the dopant material 14d, and making it possible to form the light emitting layer (co-deposition film) 5, which is a laminate structure made up of the host material layer 5a and the dopant material layer 5b, with a higher yield.

Also, in the present embodiment, the one exhaust pump 79 is connected to the first, second, third, and fourth exhaust valves 71, 73, 75, and 77, thus making it possible to simplify the device configuration of the vapor deposition device 11 in comparison to the case of providing a separate exhaust pump for each of the first, second, third, and fourth exhaust valves 71, 73, 75, and 77.

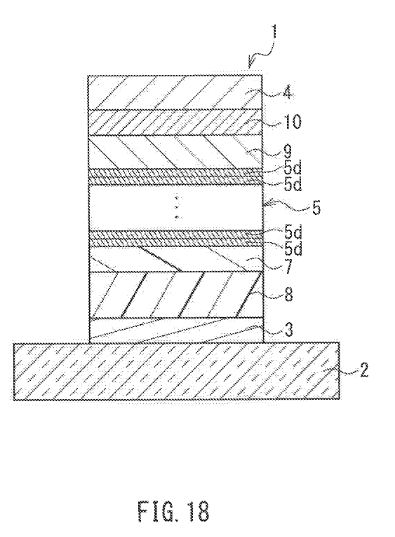

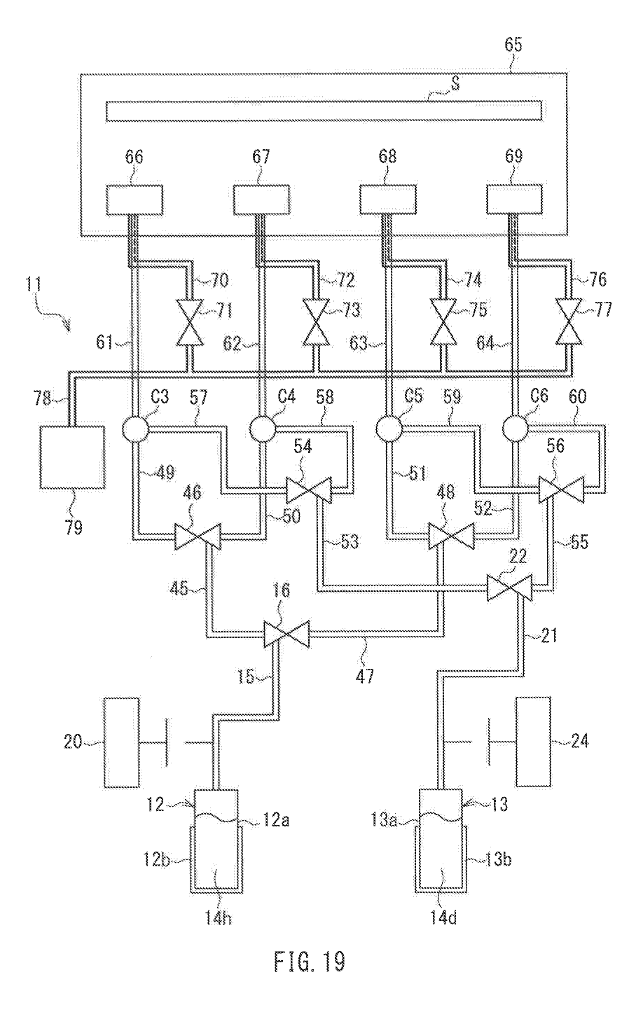

FIG. 18 is a cross-sectional diagram showing the configuration of an organic EL element according to a fourth embodiment of the present invention. FIG. 19 is a diagram illustrating a vapor deposition device according to a fourth embodiment of the present invention.

A main difference between the present embodiment and the third embodiment in these figures is that the vapor deposition device is an inline type of vapor deposition device in which vapor deposition particles of the host material and vapor deposition particles of the dopant material are emitted onto one substrate so as to be overlapped on the substrate, thus forming a light emitting layer using vapor deposition particles that are a mixture of these vapor deposition materials. Note that elements that are in common with the third embodiment are denoted by the same reference signs, and redundant descriptions will not be given for them.

Specifically, in FIG. 18, the light emitting layer 5 of the organic EL element 1 of the present embodiment is constituted by a laminate structure (co-deposition film) obtained by laminating multiple mixed layers 5d that are made up of vapor deposition particles that are a mixture of vapor deposition particles of the host material 14h and vapor deposition particles of the dopant material 14d.

Also, in the vapor deposition device 11 of the present embodiment, the first to fourth sub vapor deposition steps shown in FIG. 13 are performed similarly to the vapor deposition device of the third embodiment. Specifically, in the vapor deposition device 11 of the present embodiment, vapor deposition particles of the host material 14h from the first vapor deposition source 12 are emitted from any one vapor deposition particle emission source among the first to fourth vapor deposition particle emission sources 66 to 69, and vapor deposition particles of the dopant material 14d from the second vapor deposition source 13 are emitted from any one vapor deposition particle emission source among the first to fourth vapor deposition particle emission sources 66 to 69 that is different from the vapor deposition particle emission source that emits vapor deposition particles of the host material 14h.

Also, in the vapor deposition device 11 of the present embodiment, unlike the vapor deposition device of the third embodiment, in the first to fourth sub vapor deposition steps, vapor deposition particles of the host material 14h and vapor deposition particles of the dopant material 14d are emitted so as to be overlapped on the substrate S, and the light emitting layer 5 made up of the mixed layers 5d is formed.

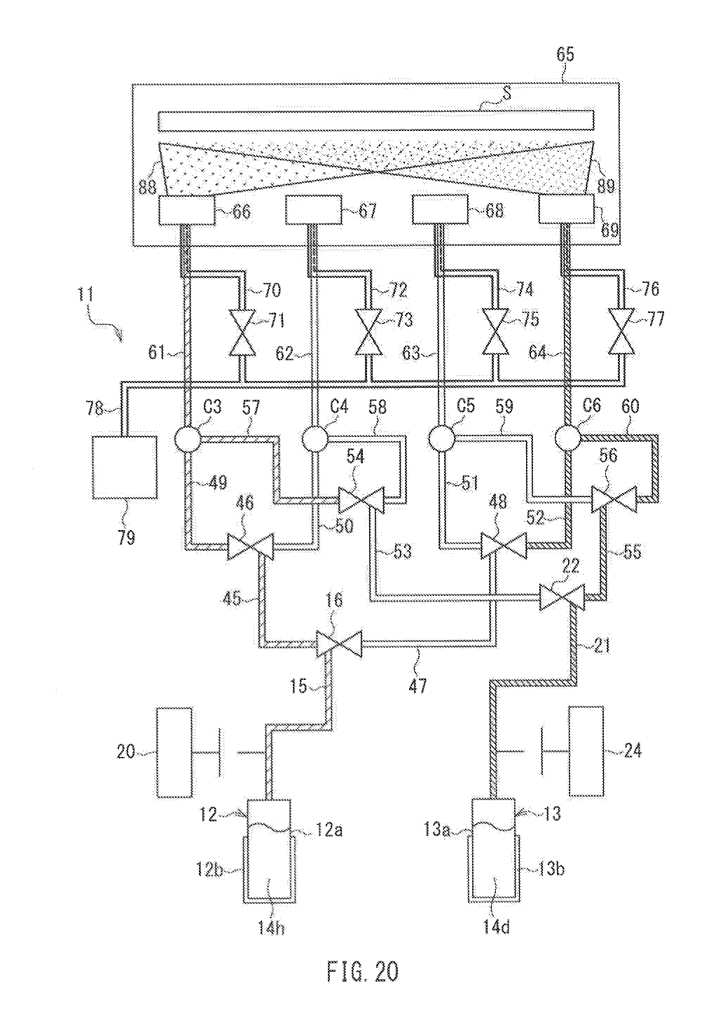

Next, a vapor deposition method performed by the vapor deposition device 11 of the present embodiment will be described in detail with reference to FIGS. 20 to 23 as well.

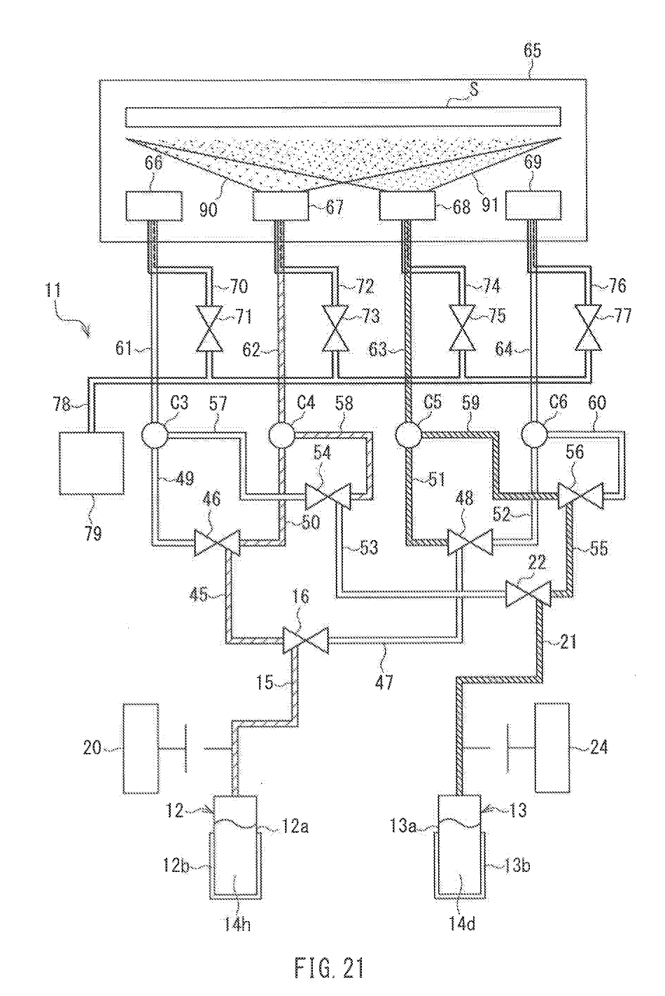

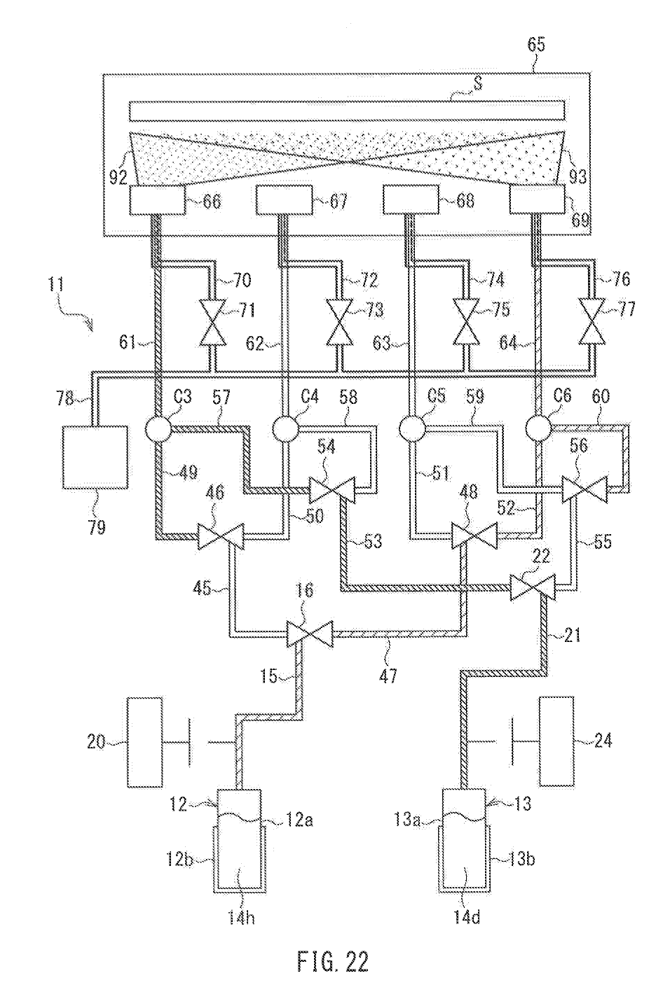

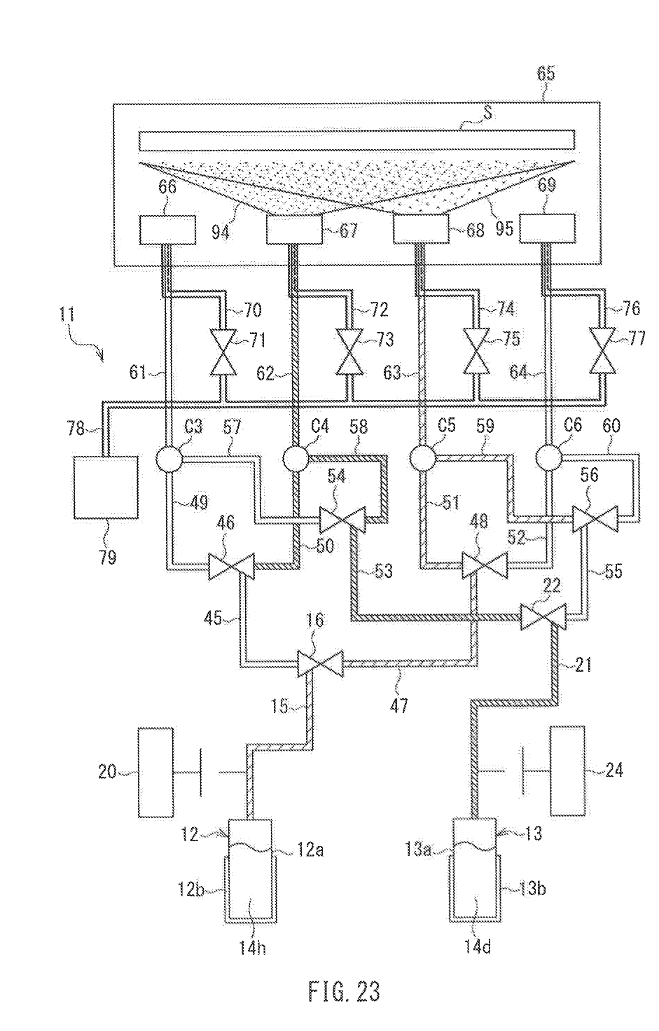

FIG. 20 is a diagram illustrating an operation state of the vapor deposition device shown in FIG. 19 in the first sub vapor deposition step. FIG. 21 is a diagram illustrating an operation state of the vapor deposition device shown in FIG. 19 in the second sub vapor deposition step. FIG. 22 is a diagram illustrating an operation state of the vapor deposition device shown in FIG. 19 in the third sub vapor deposition step. FIG. 23 is a diagram illustrating an operation state of the vapor deposition device shown in FIG. 19 in the fourth sub vapor deposition step.

As described above, in the vapor deposition device 11 of the present embodiment, the vapor deposition step includes first to fourth sub vapor deposition steps. Also, as shown in step S8 in FIG. 13, in the present embodiment, first, a first sub vapor deposition step is performed in which vapor deposition particles of the host material 14h from the first vapor deposition source 12 are emitted from the first vapor deposition particle emission source 66 onto the substrate S, and vapor deposition particles of the dopant material 14d from the second vapor deposition source 13 are emitted from the fourth vapor deposition particle emission source 69 onto the substrate S.

Specifically, in FIG. 20, in the first sub vapor deposition step, the third switching valve 46 side of the first switching valve 16 is opened, and the sixth switching valve 56 side of the second switching valve 22 is opened. Also, the junction point C3 side of the third switching valve 46 is opened, and the junction point C5 side of the fourth switching valve 48 is opened. Also, the junction point C4 side of the fifth switching valve 54 is opened, and the junction point C6 side of the sixth switching valve 56 is opened. Also, the first and fourth exhaust valves 71 and 77 are closed.

Also, in the first sub vapor deposition step, vapor deposition particles of the host material 14h from the first vapor deposition source 12 flow inside the pipes 15, 45, 49, 57, and 61 as shown by left-downward diagonal hatching in FIG. 20, and are emitted from the first vapor deposition particle emission source 66 onto the substrate S as vapor deposition particles 88. At the same time, vapor deposition particles of the dopant material 14d from the second vapor deposition source 13 flow inside the pipes 21, 55, 60, 52, and 64 as shown by right-downward diagonal hatching in FIG. 20, and are emitted from the fourth vapor deposition particle emission source 69 onto the substrate S as vapor deposition particles 89. Also, vapor deposition particles of the host material 14h and vapor deposition particles of the dopant material 14d are emitted over the entire surface of the substrate S so as to be overlapped with each other.

Also, in the first sub vapor deposition step, the second and third exhaust valves 73 and 75 are open, and the exhaust pump 79 evacuates, to the outside, vapor deposition particles that are inside the second and third vapor deposition particle emission sources 67 and 68, inside the second and third exhaust valves 73 and 75, inside the pipes 72, 74, and 78, inside the pipes 62, 50, 58, 53, 63, 51, 59, and 47, inside the junction points C4 and C5, inside the pipe 47 side of the first switching valve 16, inside the pipe 53 side of the second switching valve 22, inside the pipe 50 side of the third switching valve 46, inside the pipe 51 side of the fourth switching valve 48, inside the pipe 58 side of the fifth switching valve 54, and inside the pipe 59 side of the sixth switching valve 56.

Next, as shown in step S9 in FIG. 13, in the present embodiment, a second sub vapor deposition step is performed in which vapor deposition particles of the host material 14h from the first vapor deposition source 12 are emitted from the second vapor deposition particle emission source 67 onto the substrate S, and vapor deposition particles of the dopant material 14d from the second vapor deposition source 13 are emitted from the third vapor deposition particle emission source 68 onto the substrate S.

Specifically, in FIG. 21, in the second sub vapor deposition step, the third switching valve 46 side of the first switching valve 16 is opened, and the sixth switching valve 56 side of the second switching valve 22 is opened. Also, the junction point C4 side of the third switching valve 46 is opened, and the junction point C6 side of the fourth switching valve 48 is opened. Also, the junction point C3 side of the fifth switching valve 54 is opened, and the junction point C5 side of the sixth switching valve 56 is opened. Also, the second and third exhaust valves 73 and 75 are closed.

Also, in the second sub vapor deposition step, vapor deposition particles of the host material 14h from the first vapor deposition source 12 flow inside the pipes 15, 45, 50, 58, and 62 as shown by left-downward diagonal hatching in FIG. 21, and are emitted from the second vapor deposition particle emission source 67 onto the substrate S as vapor deposition particles 90. At the same time, vapor deposition particles of the dopant material 14d from the second vapor deposition source 13 flow inside the pipes 21, 55, 59, 51, and 63 as shown by right-downward diagonal hatching in FIG. 21, and are emitted from the third vapor deposition particle emission source 68 onto the substrate S as vapor deposition particles 91. Also, vapor deposition particles of the host material 14h and vapor deposition particles of the dopant material 14d are emitted over the entire surface of the substrate S so as to be overlapped with each other.

Also, up to the point in time immediately before the second sub vapor deposition step (i.e., during the first sub vapor deposition step), the inside of the second and third vapor deposition particle emission sources 67 and 68 and the inside of the pipes 50, 51, 58, 59, 62, and 63 have been evacuated by the exhaust pump 79, and therefore corresponding vapor deposition particles can be vapor deposited in the second sub vapor deposition step while preventing contaminants and different materials from becoming mixed in.

Also, in the second sub vapor deposition step, the first and fourth exhaust valves 71 and 77 are open, and the exhaust pump 79 evacuates, to the outside, vapor deposition particles that are inside the first and fourth vapor deposition particle emission sources 66 and 69, inside the first and fourth exhaust valves 71 and 77, inside the pipes 70, 76, and 78, inside the pipes 61, 49, 57, 53, 64, 52, 60, and 47, inside the junction points C3 and C6, inside the pipe 47 side of the first switching valve 16, inside the pipe 53 side of the second switching valve 22, inside the pipe 49 side of the third switching valve 46, inside the pipe 52 side of the fourth switching valve 48, inside the pipe 57 side of the fifth switching valve 54, and inside the pipe 60 side of the sixth switching valve 56.

Next, as shown in step S10 in FIG. 13, in the present embodiment, a third sub vapor deposition step is performed in which vapor deposition particles of the host material 14h from the first vapor deposition source 12 are emitted from the fourth vapor deposition particle emission source 69 onto the substrate S, and vapor deposition particles of the dopant material 14d from the second vapor deposition source 13 are emitted from the first vapor deposition particle emission source 66 onto the substrate S.

Specifically, in FIG. 22, in the third sub vapor deposition step, the fourth switching valve 48 side of the first switching valve 16 is opened, and the fifth switching valve 54 side of the second switching valve 22 is opened. Also, the junction point C3 side of the third switching valve 46 is opened, and the junction point C6 side of the fourth switching valve 48 is opened. Also, the junction point C4 side of the fifth switching valve 54 is opened, and the junction point C5 side of the sixth switching valve 56 is opened. Also, the first and fourth exhaust valves 71 and 77 are closed.

Also, in the third sub vapor deposition step, vapor deposition particles of the host material 14h from the first vapor deposition source 12 flow inside the pipes 15, 47, 52, 60, and 64 as shown by left-downward diagonal hatching in FIG. 22, and are emitted from the fourth vapor deposition particle emission source 69 onto the substrate S as vapor deposition particles 93. At the same time, vapor deposition particles of the dopant material 14d from the second vapor deposition source 13 flow inside the pipes 21, 53, 57, 49, and 61 as shown by right-downward diagonal hatching in FIG. 22, and are emitted from the first vapor deposition particle emission source 66 onto the substrate S as vapor deposition particles 92. Also, vapor deposition particles of the host material 14h and vapor deposition particles of the dopant material 14d are emitted over the entire surface of the substrate S so as to be overlapped with each other.

Also, up to the point in time immediately before the third sub vapor deposition step (i.e., during the second sub vapor deposition step), the inside of the first and fourth vapor deposition particle emission sources 66 and 69 and the inside of the pipes 49, 52, 57, 60, 61, and 64 have been evacuated by the exhaust pump 79, and therefore corresponding vapor deposition particles can be vapor deposited in the third sub vapor deposition step while preventing contaminants and different materials from becoming mixed in.

Also, in the third sub vapor deposition step, the second and third exhaust valves 73 and 75 are open, and the exhaust pump 79 evacuates, to the outside, vapor deposition particles that are inside the second and third vapor deposition particle emission sources 67 and 68, inside the second and third exhaust valves 73 and 75, inside the pipes 72, 74, and 78, inside the pipes 62, 50, 58, 45, 63, 51, 59, and 55, inside the junction points C4 and C5, inside the pipe 45 side of the first switching valve 16, inside the pipe 55 side of the second switching valve 22, inside the pipe 50 side of the third switching valve 46, inside the pipe 51 side of the fourth switching valve 48, inside the pipe 58 side of the fifth switching valve 54, and inside the pipe 59 side of the sixth switching valve 56.

Next, as shown in step S11 in FIG. 13, in the present embodiment, a fourth sub vapor deposition step is performed in which vapor deposition particles of the host material 14h from the first vapor deposition source 12 are emitted from the third vapor deposition particle emission source 68 onto the substrate S, and vapor deposition particles of the dopant material 14d from the second vapor deposition source 13 are emitted from the second vapor deposition particle emission source 67 onto the substrate S.

Specifically, in FIG. 23, in the fourth sub vapor deposition step, the fourth switching valve 48 side of the first switching valve 16 is opened, and the fifth switching valve 54 side of the second switching valve 22 is opened. Also, the junction point C3 side of the third switching valve 46 is opened, and the junction point C5 side of the fourth switching valve 48 is opened. Also, the junction point C4 side of the fifth switching valve 54 is opened, and the junction point C6 side of the sixth switching valve 56 is opened. Also, the second and third exhaust valves 73 and 75 are closed.

Also, in the fourth sub vapor deposition step, vapor deposition particles of the host material 14h from the first vapor deposition source 12 flow inside the pipes 15, 47, 51, 59, and 63 as shown by left-downward diagonal hatching in FIG. 23, and are emitted from the third vapor deposition particle emission source 68 onto the substrate S as vapor deposition particles 95. At the same time, vapor deposition particles of the dopant material 14d from the second vapor deposition source 13 flow inside the pipes 21, 53, 58, 50, and 62 as shown by right-downward diagonal hatching in FIG. 23, and are emitted from the second vapor deposition particle emission source 67 onto the substrate S as vapor deposition particles 94. Also, vapor deposition particles of the host material 14h and vapor deposition particles of the dopant material 14d are emitted over the entire surface of the substrate S so as to be overlapped with each other.

Also, up to the point in time immediately before the fourth sub vapor deposition step (i.e., during the third sub vapor deposition step), the inside of the second and third vapor deposition particle emission sources 67 and 68 and the inside of the pipes 50, 51, 58, 59, 62, and 63 have been evacuated by the exhaust pump 79, and therefore corresponding vapor deposition particles can be vapor deposited in the fourth sub vapor deposition step while preventing contaminants and different materials from becoming mixed in.

Also, in the fourth sub vapor deposition step, the first and fourth exhaust valves 71 and 77 are open, and the exhaust pump 79 evacuates, to the outside, vapor deposition particles that are inside the first and fourth vapor deposition particle emission sources 66 and 69, inside the first and fourth exhaust valves 71 and 77, inside the pipes 70, 76, and 78, inside the pipes 61, 49, 57, 45, 64, 52, 60, and 55, inside the junction points C3 and C6, inside the pipe 45 side of the first switching valve 16, inside the pipe 55 side of the second switching valve 22, inside the pipe 49 side of the third switching valve 46, inside the pipe 52 side of the fourth switching valve 48, inside the pipe 57 side of the fifth switching valve 54, and inside the pipe 60 side of the sixth switching valve 56.

According to the above configuration, actions and effects similar to those of the third embodiment can be achieved in the present embodiment. Also, in the present embodiment, vapor deposition particles of the host material 14h and the dopant material 14d are emitted onto the substrate S at the same time so as to be overlapped with each other, thus making it possible to efficiently form the light emitting layer (co-deposition film) 5 in which vapor deposition particles of the host material 14h and vapor deposition particles of the dopant material 14d are mixed, and making it possible to form a more homogenous light emitting layer 5.

Note that the above-described embodiments are all illustrative and not limiting. The technical scope of the present invention is defined by the claims, and all changes within a range equivalent to the configurations recited in the claims are also included in the technical scope of the present invention.

For example, although cases of forming the light emitting layer of an organic EL element using a vapor deposition device and a vapor deposition method of the present invention are described above, the present invention is not limited to this, and there are no particular limitations on the present invention as long as a co-deposition film (film) is formed by performing co-deposition of vapor deposition particles of two or more types of materials produced by multiple vapor deposition sources. Specifically, another constituent element such as the hole injection layer of an organic EL element may be formed. Also, the present invention is applicable to another organic element such as an organic thin-film solar cell or an organic thin-film diode, or another element that has a co-deposition film, for example.

Also, although configurations in which a light emitting layer, a hole transport layer, and an electron transport layer are provided separately are described in the first to fourth embodiments, the organic EL element of the present invention is not limited to this, and a configuration is possible in which the light emitting layer also functions as the hole transport layer, and the light emitting layer also functions as the electron transport layer.

The present invention is useful to a vapor deposition device and a vapor deposition method that, even when performing co-deposition of two or more types of materials, can precisely form the co-deposition film, and an organic EL element using the same.

### DESCRIPTION OF REFERENCE NUMERALS

1 Organic EL element
5 Light emitting layer (film)
5a Host material layer
5b Dopant material layer
5c Assist material layer
11 Vapor deposition device
12 First vapor deposition source
13 Second vapor deposition source
14h Host material
14d Dopant material
14a Assist material
16 First switching valve
20 First exhaust pump
22 Second switching valve
26 Second exhaust pump
27, 42 Common pipe
29, 43 Vapor deposition particle emission source
32 Exhaust valve
34, 79 Exhaust pump
35 Third vapor deposition source
37 Third switching valve
41 Third exhaust pump
46 Third switching valve
48 Fourth switching valve
54 Fifth switching valve
56 Sixth switching valve
61 First common pipe
62 Second common pipe
63 Third common pipe
64 Fourth common pipe
66 First vapor deposition particle emission source
67 Second vapor deposition particle emission source
68 Third vapor deposition particle emission source
69 Fourth vapor deposition particle emission source
71 First exhaust valve
73 Second exhaust valve
75 Third exhaust valve
77 Fourth exhaust valve
CP1, CP2, CP3 Control plate

1. A vapor deposition device comprising:
a plurality of vapor deposition sources;
at least one common pipe that is connected to the plurality of vapor deposition sources;
at least one vapor deposition particle emission source that is connected to the at least one common pipe and emits vapor deposition particles from each of the vapor deposition sources;
an exhaust valve that is connected to the at least one vapor deposition particle emission source; and
an exhaust pump that is connected to the exhaust valve.

2. The vapor deposition device of claim 1,
wherein included among the plurality of vapor deposition sources are a first vapor deposition source that produces vapor deposition particles of a host material and a second vapor deposition source that produces vapor deposition particles of a dopant material, and
the vapor deposition particles of the host material from the first vapor deposition source and the vapor deposition particles of the dopant material from the second vapor deposition source are alternatingly passed through the one common pipe and emitted from the one vapor deposition particle emission source.

3. The vapor deposition device of claim 2,
wherein the first vapor deposition source is connected to the one common pipe via a first switching valve,
the second vapor deposition source is connected to the one common pipe via a second switching valve,
a first exhaust pump for evacuating the vapor deposition particles of the host material from the first vapor deposition source is connected to the first switching valve, and
a second exhaust pump for evacuating the vapor deposition particles of the dopant material from the second vapor deposition source is connected to the second switching valve.

4. The vapor deposition device of claim 1,
wherein included among the plurality of vapor deposition sources are a first vapor deposition source that produces vapor deposition particles of a host material, a second vapor deposition source that produces vapor deposition particles of a dopant material, and a third vapor deposition source that produces vapor deposition particles of an assist material, and
the vapor deposition particles of the host material from the first vapor deposition source, the vapor deposition particles of the dopant material from the second vapor deposition source, and the vapor deposition particles of the assist material from the third vapor deposition source are successively passed through the one common pipe and emitted from the one vapor deposition particle emission source.

5. The vapor deposition device of claim 4,
wherein the first vapor deposition source is connected to the one common pipe via a first switching valve,
the second vapor deposition source is connected to the one common pipe via a second switching valve,
the third vapor deposition source is connected to the one common pipe via a third switching valve,
a first exhaust pump for evacuating the vapor deposition particles of the host material from the first vapor deposition source is connected to the first switching valve,
a second exhaust pump for evacuating the vapor deposition particles of the dopant material from the second vapor deposition source is connected to the second switching valve, and
a third exhaust pump for evacuating the vapor deposition particles of the assist material from the third vapor deposition source is connected to the third switching valve.

6. The vapor deposition device of claim 1,
wherein included among the plurality of vapor deposition sources are a first vapor deposition source that produces vapor deposition particles of a host material and a second vapor deposition source that produces vapor deposition particles of a dopant material,
first, second, third, and fourth common pipes are provided as the at least one common pipe,
first, second, third, and fourth vapor deposition particle emission sources that are respectively connected to the first, second, third, and fourth common pipes are provided as the at least one vapor deposition particle emission source,
first, second, third, and fourth exhaust valves that are respectively connected to the first, second, third, and fourth vapor deposition particle emission sources are provided as the exhaust valve,
the first vapor deposition source is connected to the first and second common pipes via first and third switching valves, and the first vapor deposition source is connected to the third and fourth common pipes via first and fourth switching valves, and
the second vapor deposition source is connected to the first and second common pipes via second and fifth switching valves, and the second vapor deposition source is connected to the third and fourth common pipes via second and sixth switching valves.

7. The vapor deposition device of claim 6, wherein one exhaust pump is connected to the first, second, third, and fourth exhaust valves.

8. The vapor deposition device of claim 1, wherein a rate monitor is provided between the at least one common pipe and each of the vapor deposition sources, and each rate monitor monitors a production amount of vapor deposition particles from the corresponding vapor deposition source.

9. The vapor deposition device of claim 1, wherein a crucible and a heater that heats the interior of the crucible are included in each of the vapor deposition sources.

10. A vapor deposition method of performing a vapor deposition step of forming a film by depositing vapor deposition particles onto a substrate with use of a vapor deposition device that includes a plurality of vapor deposition sources, at least one common pipe that is connected to the plurality of vapor deposition sources, at least one vapor deposition particle emission source that is connected to the at least one common pipe and emits vapor deposition particles from each of the vapor deposition sources, an exhaust valve that is connected to the at least one vapor deposition particle emission source, and an exhaust pump that is connected to the exhaust valve,
wherein in the vapor deposition step, a host material layer made up of vapor deposition particles of a host material and a dopant material layer made up of vapor deposition particles of a dopant material are vapor deposited by alternatingly operating first and second switching valves respectively connected to first and second vapor deposition sources so as to alternatingly connect the first and second vapor deposition sources to one common pipe.

11. The vapor deposition method of claim 10,
wherein in the vapor deposition step, a host material layer formation step of forming the host material layer and a dopant material layer formation step of forming the dopant material layer are performed successively,
in the host material layer formation step,
a mid-vapor deposition step is a step in which
the first and second vapor deposition sources operate at the same time,
the first switching valve connects the first vapor deposition source to the one common pipe,
the second switching valve connects the second vapor deposition source to a second exhaust pump,
the exhaust valve is closed, and
the second exhaust pump operates, and
a post-vapor deposition step is a step in which
the first and second vapor deposition sources operate at the same time,
the first switching valve connects the first vapor deposition source to a first exhaust pump,
the second switching valve connects the second vapor deposition source to the second exhaust pump,
the exhaust valve is open, and
the first and second exhaust pumps and the exhaust pump operate, and
in the dopant material layer formation step,
a mid-vapor deposition step is a step in which
the first and second vapor deposition sources operate at the same time,
the first switching valve connects the first vapor deposition source to the first exhaust pump,
the second switching valve connects the second vapor deposition source to the one common pipe,
the exhaust valve is closed, and
the first exhaust pump operates, and
a post-vapor deposition step is a step in which
the first and second vapor deposition sources operate at the same time,
the first switching valve connects the first vapor deposition source to the first exhaust pump,
the second switching valve connects the second vapor deposition source to the second exhaust pump,
the exhaust valve is open, and
the first and second exhaust pumps and the exhaust pump operate.

12. The vapor deposition method of claim 10,
wherein in the vapor deposition step, a host material layer formation step of forming the host material layer, a dopant material layer formation step of forming the dopant material layer, and an assist material layer formation step of forming an assist material layer made up of vapor deposition particles of an assist material are performed successively,
in the host material layer formation step,
a mid-vapor deposition step is a step in which
the first and second vapor deposition sources and a third vapor deposition source operate at the same time,
the first switching valve connects the first vapor deposition source to the one common pipe,
the second switching valve connects the second vapor deposition source to a second exhaust pump,
a third switching valve connects the third vapor deposition source to a third exhaust pump,
the exhaust valve is closed, and
the second and third exhaust pumps operate, and
a post-vapor deposition step is a step in which
the first, second, and third vapor deposition sources operate at the same time,
the first switching valve connects the first vapor deposition source to a first exhaust pump,
the second switching valve connects the second vapor deposition source to the second exhaust pump,
the third switching valve connects the third vapor deposition source to the third exhaust pump,
the exhaust valve is open, and
the first, second, and third exhaust pumps and the exhaust pump operate,
in the dopant material layer formation step,
a mid-vapor deposition step is a step in which
the first, second, and third vapor deposition sources operate at the same time,
the first switching valve connects the first vapor deposition source to the first exhaust pump,
the second switching valve connects the second vapor deposition source to the one common pipe,
the third switching valve connects the third vapor deposition source to the third exhaust pump,
the exhaust valve is closed, and
the first and third exhaust pumps operate, and
a post-vapor deposition step is a step in which
the first, second, and third vapor deposition sources operate at the same time,
the first switching valve connects the first vapor deposition source to the first exhaust pump,
the second switching valve connects the second vapor deposition source to the second exhaust pump,
the third switching valve connects the third vapor deposition source to the third exhaust pump,
the exhaust valve is open, and
the first, second, and third exhaust pumps and the exhaust pump operate, and
in the assist material layer formation step,
a mid-vapor deposition step is a step in which
the first, second, and third vapor deposition sources operate at the same time,
the first switching valve connects the first vapor deposition source to the first exhaust pump,
the second switching valve connects the second vapor deposition source to the second exhaust pump,
the third switching valve connects the third vapor deposition source to the one common pipe,
the exhaust valve is closed, and
the first and second exhaust pumps operate, and
a post-vapor deposition step is a step in which
the first, second, and third vapor deposition sources operate at the same time,
the first switching valve connects the first vapor deposition source to the first exhaust pump,
the second switching valve connects the second vapor deposition source to the second exhaust pump,
the third switching valve connects the third vapor deposition source to the third exhaust pump,
the exhaust valve is open, and
the first, second, and third exhaust pumps and the exhaust pump operate.

13. The vapor deposition method of claim 10,
wherein the vapor deposition step includes
a first sub vapor deposition step in which the vapor deposition particles of the host material from the first vapor deposition source are emitted from the first vapor deposition particle emission source, and the vapor deposition particles of the dopant material from the second vapor deposition source are emitted from the fourth vapor deposition particle emission source,
a second sub vapor deposition step in which the vapor deposition particles of the host material from the first vapor deposition source are emitted from the second vapor deposition particle emission source, and the vapor deposition particles of the dopant material from the second vapor deposition source are emitted from the third vapor deposition particle emission source,
a third sub vapor deposition step in which the vapor deposition particles of the host material from the first vapor deposition source are emitted from the fourth vapor deposition particle emission source, and the vapor deposition particles of the dopant material from the second vapor deposition source are emitted from the first vapor deposition particle emission source, and
a fourth sub vapor deposition step in which the vapor deposition particles of the host material from the first vapor deposition source are emitted from the third vapor deposition particle emission source, and the vapor deposition particles of the dopant material from the second vapor deposition source are emitted from the second vapor deposition particle emission source.

14. The vapor deposition method of claim 13,
wherein a control plate is formed between the substrate and each pair of adjacent vapor deposition particle emission sources among the first to fourth vapor deposition particle emission sources, and
in the first, second, third, and fourth sub vapor deposition steps, the vapor deposition particles of the host material and the vapor deposition particles of the dopant material are emitted so as to not be overlapped on the substrate.

15. The vapor deposition method of claim 13, wherein in the first, second, third, and fourth sub vapor deposition steps, the vapor deposition particles of the host material and the vapor deposition particles of the dopant material are emitted so as to be overlapped on the substrate.

16. An organic EL element having the film formed using the vapor deposition method of claim 10.
